(19) United States
(12) Patent Application Publication
(10) Pub. No.: US 2025/0365915 A1
(43) Pub. Date: Nov. 27, 2025

(54) MULTI-PORT SRAM CELL WITH ENLARGED CONTACT VIAS

(71) Applicant: Taiwan Semiconductor Manufacturing Company, Ltd., Hsin-Chu (TW)

(72) Inventors: Jui-Lin Chen, Taipei City (TW); Ping-Wei Wang, Hsin-Chu (TW); Yu-Bey Wu, Hsinchu City (TW)

(21) Appl. No.: 19/287,081

(22) Filed: Jul. 31, 2025

Related U.S. Application Data
(63) Continuation of application No. 18/492,111, filed on Oct. 23, 2023.
(60) Provisional application No. 63/469,036, filed on May 25, 2023.

(51) Int. Cl. H10B 10/00

(52) U.S. Cl. CPC H10B 10/125

(57) ABSTRACT

A memory cell includes first and second active regions and first and second gate structures. The first gate structure engages the first and second active regions in forming a first pull-down transistor and a first pull-up transistor, respectively. The second gate structure engages the first and second active regions in forming a second pull-down transistor and a second pull-up transistor, respectively. The memory cell also includes a first source/drain contact via electrically coupled to the first and second pull-down transistors, a second source/drain contact via electrically coupled to the first and second pull-up transistors, a first gate contact electrically coupled to the first gate structure, and a second gate contact electrically coupled to the second gate structure. One of the first and second source/drain contact vias has an area larger than either of the first and second gate contacts in a top view of the memory cell.

### PRIORITY DATA

This is a continuation application of U.S. patent application Ser. No. 18/492,111, filed Oct. 23, 2023, which claims benefit of U.S. Provisional Patent Application No. 63/469,036, filed May 25, 2023, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Semiconductor memory is an electronic data storage device implemented on a semiconductor-based integrated circuit and has much faster access times than other types of data storage technologies. For example, static random-access memories (SRAM) devices are commonly used in integrated circuits. SRAM devices is popular in high-speed communication, image processing and system-on-chip (SOC) applications. A bit can be read from or written into the SRAM cell within a few nanoseconds, while access times for rotating storage such as hard disks is in the range of milliseconds.

When entering into deep sub-micron era, SRAM devices have become increasingly popular due to their lithography-friendly layout shapes of active regions, polysilicon lines, and metal layers. Among SRAM devices, multi-port SRAM devices have become popular. For example, a two-port (2P) SRAM device allows parallel operation, such as 1R (read) 1W (write), or 2R (read) in one cycle, and therefore has higher bandwidth than a single-port SRAM. However, in the deep sub-micron era, contact vias for multi-port SRAM cells are generally small due to limited available area, and consequently contact via resistance and overall contact resistance become high. Contact resistance, particularly contact resistance of those contacts coupled to power supply and electrical ground lines, plays a key factor to boost speed of a multi-port SRAM cell. With the advancement of process nodes, there is a need for contact via resistance reduction in multi-port SRAM cells.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a perspective view and a top view of a portion of a memory device, respectively, in accordance with some embodiments of the present disclosure.

FIG. 2 illustrates a cross-sectional view of various layers of a memory device, in accordance with some embodiments of the present disclosure.

FIG. 3 illustrates a circuit schematic for a two-port static random-access memory (SRAM) cell, in accordance with some embodiments of the present disclosure.

FIG. 4 illustrates a layout of a device layer of the two-port SRAM cell as in FIG. 3, in accordance with some embodiments of the present disclosure.

FIGS. 5, 6, 7, 8, and 9 illustrate layouts of various contact and metal layers of the two-port SRAM cell as in FIG. 3, in accordance with some embodiments of the present disclosure.

FIG. 10 illustrates a layout of an SRAM array based on the two-port SRAM cell as in FIG. 3, in accordance with some other embodiments of the present disclosure.

FIGS. 11A, 11B, and 11C illustrate diagrammatic cross-sectional views of a portion of the SRAM array as in FIG. 10, in accordance with some other embodiments of the present disclosure.

FIG. 12 illustrates a circuit schematic for a two-port SRAM cell, in accordance with some embodiments of the present disclosure.

FIG. 13 illustrates a layout of a device layer of the two-port SRAM cell as in FIG. 12, in accordance with some embodiments of the present disclosure.

FIGS. 14, 15, 16, 17, and 18 illustrate layouts of various contact and metal layers of the two-port SRAM cell as in FIG. 12, in accordance with some embodiments of the present disclosure.

FIG. 19 illustrates a layout of an SRAM array based on the two-port SRAM cell as in FIG. 12, in accordance with some other embodiments of the present disclosure.

FIGS. 20A, 20B, and 20C illustrate diagrammatic cross-sectional views of a portion of the SRAM array as in FIG. 19, in accordance with some other embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to static random-access memories (SRAM) structures, more particularly, multi-port SRAM cells. An SRAM cell includes transistors with metal interconnect structures above the transistors. The metal interconnect structures include metal tracks (metal lines) for interconnecting transistor gates and source/drain regions, such as signal metal tracks for routing bit line and word line signals to the cell components, as well as power metal tracks for providing power to the cell components. Contacts and respective contact vias electrically connect the cell components to the signal metal tracks and the power metal tracks. For example, some of the source/drain (S/D) regions in an SRAM cell are coupled to a power voltage VDD (also referred to as VCC) and/or an electrical ground VSS through source/drain contacts and respective contact vias. Source/drain region(s) may refer to a source or a drain, individually or collectively dependent upon the context.

With the increasing down-scaling of SRAM cells, available layout area for contact vias also becomes smaller. Accordingly, the contact via resistance and consequently overall contact resistance of the electrical contacts becomes increasingly higher. The contact resistance to the source/drain regions in an SRAM cell, particularly those associated with power routing resistance, thus becomes a key issue in further boosting SRAM performance.

The present disclosure provides exemplary circuits, in accordance with multi-port SRAM cell layout designs, for providing sufficient layout resources for contact vias. In some embodiments, the layout designs indicate a two-port (2P) SRAM cell with larger layout area devoted to those contact vias in association with power routings. With the larger layout area and consequently larger contact via sizes, the contact via resistance is reduced, and a boost to multi-port SRAM cell performance is achieved.

Some exemplary embodiments are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the fin-like field-effect transistor (FinFET). The FinFET gets its name from the fin-like structure which extends from a substrate on which it is formed, and which is used to form the FET channel. Another multi-gate device, introduced in part to address performance challenges associated with the FinFET, is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

The details of the device structures of the present disclosure are described in the attached drawings. The drawings have outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

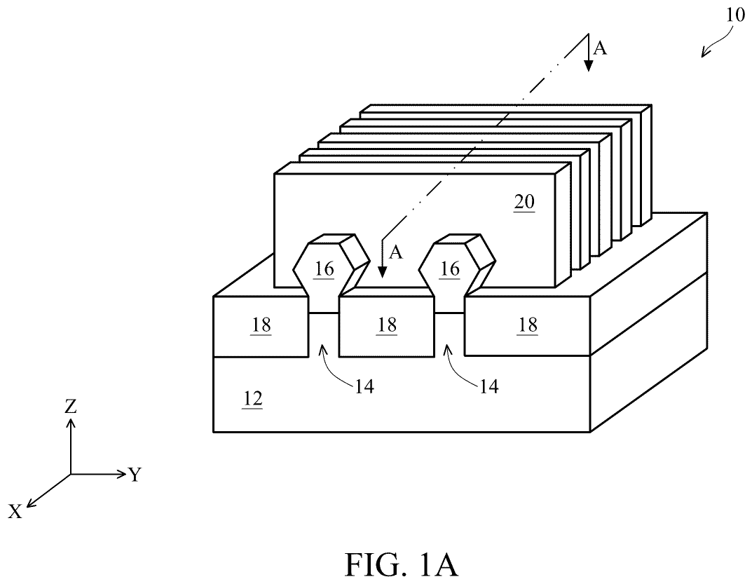

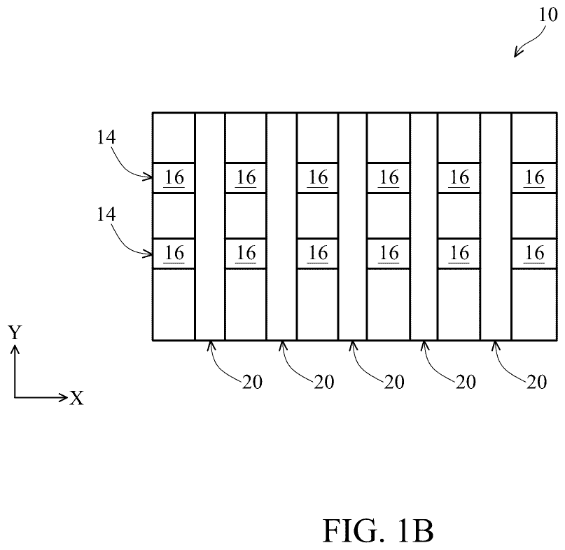

FIGS. 1A and 1B illustrate a perspective view and a top view, respectively, of a portion of an Integrated Circuit (IC) device 10, such as an SRAM device, that is implemented using GAA transistors. Referring to FIG. 1A, the IC device 10 includes a substrate 12. The substrate 12 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GalnAs, GaInP, GaInAsP, and/or other suitable materials. The substrate 12 may be a single-layer material having a uniform composition. Alternatively, the substrate 12 may include multiple material layers having similar or different compositions suitable for IC device manufacturing. In one example, the substrate 12 may be a silicon-on-insulator (SOI) substrate having a semiconductor silicon layer formed on a silicon oxide layer. In another example, the substrate 12 may include a conductive layer, a semiconductor layer, a dielectric layer, other layers, or combinations thereof. Various doped regions, such as source/drain (S/D) regions, may be formed in or on the substrate 12. The doped regions may be doped with n-type dopants, such as phosphorus or arsenic, and/or p-type dopants, such as boron, depending on design requirements. The doped regions may be formed directly on the substrate 12, in a p-well structure, in an n-well structure, in a dual-well structure, or using a raised structure. Doped regions may be formed by implantation of dopant atoms, in-situ doped epitaxial growth, and/or other suitable techniques.

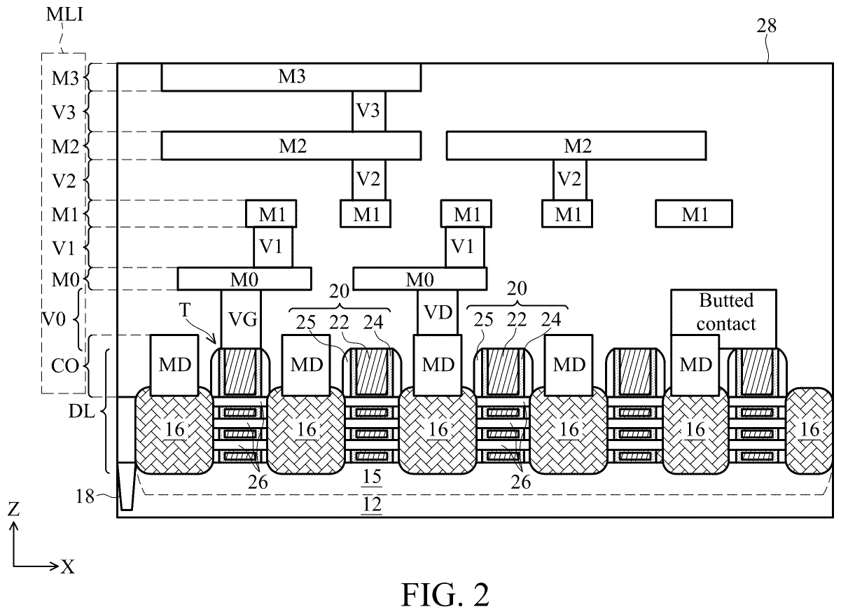

Three-dimensional active regions 14 are formed on the substrate 12. An active region for a transistor refers to the area where a source region, a drain region, and a channel region under a gate structure of the transistor are formed. An active region is also referred to as an “oxide-definition (OD) region” in the context. Each of the active regions 14 includes elongated nanostructures 26 (as shown in FIG. 2) vertically stacked in channel regions defined in the active region and above a fin-shape base. The fin-shape base protrudes upwardly out of the substrate 12. Source/drain features 16 are formed in source/drain regions defined in the active region and over the fin-shape base. The source/drain features 16 abut two opposing ends of the nanostructures 26. The source/drain features 16 may include epi-layers that are epitaxially grown on the fin-shape base.

The IC device 10 further includes isolation structures (or isolation features) 18 formed over the substrate 12. The isolation structures 18 electrically separate various components of the IC device 10. The isolation structures 18 may include silicon oxide, silicon nitride, silicon oxynitride, fluoride-doped silicate glass (FSG), a low-k dielectric material, and/or other suitable materials. In some embodiments, the isolation structures 18 may include shallow trench isolation (STI) features. In one embodiment, the isolation structures 18 are formed by etching trenches in the substrate 12 during the formation of the active regions 14. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 18. Alternatively, the isolation structures 18 may include a multi-layer structure, for example, having one or more thermal oxide liner layers.

The IC device 10 also includes gate structures (or gate stacks) 20 formed over and engaging the active regions 14. The gate structures 20 may be dummy gate structures (e.g., containing an oxide gate dielectric and a polysilicon gate electrode), or they may be high-k metal gate (HKMG) structures that contain a high-k gate dielectric and a metal gate electrode, where the HKMG structures are formed by replacing the dummy gate structures. Though not depicted herein, the gate structures 20 may include additional material layers, such as an interfacial layer, a capping layer, other suitable layers, or combinations thereof.

Referring to FIG. 1B, multiple active regions 14 are oriented lengthwise along the X-direction, and multiple gate structures 20 are oriented lengthwise along the Y-direction, i.e., generally perpendicular to the active regions 14. At intersections of the active regions 14 and the gate structures 20, transistors are formed. In many embodiments, the IC device 10 includes additional features such as gate spacers disposed along sidewalls of the gate structures 20, and numerous other features.

FIG. 2 is a fragmentary diagrammatic cross-sectional view along A-A line of FIG. 1A, which shows various layers (levels) that can be fabricated over the substrate 12, according to various aspects of the present disclosure. In FIG. 2, the various layers include a device layer DL and metal interconnect structures (also collectively referred to as multilayer interconnect MLI) disposed over the device layer DL. Device layer DL includes devices (e.g., transistors, resistors, capacitors, and/or inductors) and/or device components (e.g., doped wells, gate structures, and/or source/drain features). In some embodiments, device layer DL includes the substrate 12, doped regions 15 disposed in the substrate 12 (e.g., n-wells and/or p-wells), isolation features 18, and transistors T. In the depicted embodiment, transistors T include suspended nanostructures (channel layers) 26 and the gate structures 20 disposed between source/drain features 16, where the gate structures 20 wrap and/or surround the suspended nanostructures 26. The nanostructures 26 may include nanosheets, nanotubes, or nanowires, or some other type of nanostructure that extends horizontally in the X-direction. Each gate structure 20 has a metal gate structure formed from a gate electrode 22 disposed over a gate dielectric 24 and gate spacers 25 disposed along sidewalls of the metal gate structure.

Multilayer interconnect MLI electrically couples various devices and/or components of device layer DL, such that the various devices and/or components can operate as specified by design requirements for the memory. In the depicted embodiment, multilayer interconnect MLI includes a contact layer (CO level), a via zero layer (V0 level), a metal zero (M0) level, a via one layer (V1 level), a metal one layer (M1 level), a via two layer (V2 level), a metal two layer (M2 level), a via three layer (V3 level), and a metal three layer (M3 level). The present disclosure contemplates multilayer interconnect MLI having more or less layers and/or levels, for example, a total number of N metal layers (levels) of the multilayer interconnect MLI with N as an integer ranging from 2 to 10. Each level of multilayer interconnect MLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of multilayer interconnect MLI, such as M0 level, are formed simultaneously. In some embodiments, conductive features at a same level of multilayer interconnect MLI have top surfaces that are substantially planar with one another and/or bottom surfaces that are substantially planar with one another. CO level includes source/drain contacts (MD) disposed in a dielectric layer 28; V0 level includes gate vias VG, source/drain contact vias VD, and butted contacts disposed in the dielectric layer 28; M0 level includes M0 metal lines disposed in dielectric layer 28, where gate vias VG connect gate structures to M0 metal lines, source/drain vias V0 connect source/drains to M0 metal lines, and butted contacts connect gate structures and source/drains together and to M0 metal lines; V1 level includes V1 vias disposed in the dielectric layer 28, where V1 vias connect M0 metal lines to M1 metal lines; M1 level includes M1 metal lines disposed in the dielectric layer 28; V2 level includes V2 vias disposed in the dielectric layer 28, where V2 vias connect M1 lines to M2 lines; M2 level includes M2 metal lines disposed in the dielectric layer 28; V3 level includes V3 vias disposed in the dielectric layer 28, where V3 vias connect M2 lines to M3 lines. FIG. 2 has been simplified for the sake of clarity to better understand the inventive concepts of the present disclosure. Additional features can be added in the various layers of the memory, and some of the features described can be replaced, modified, or eliminated in other embodiments of the memory. FIG. 2 is merely an example and may not reflect an actual cross-sectional view of the IC device 10 and/or the SRAM cells 100 that is discussed in further detail below.

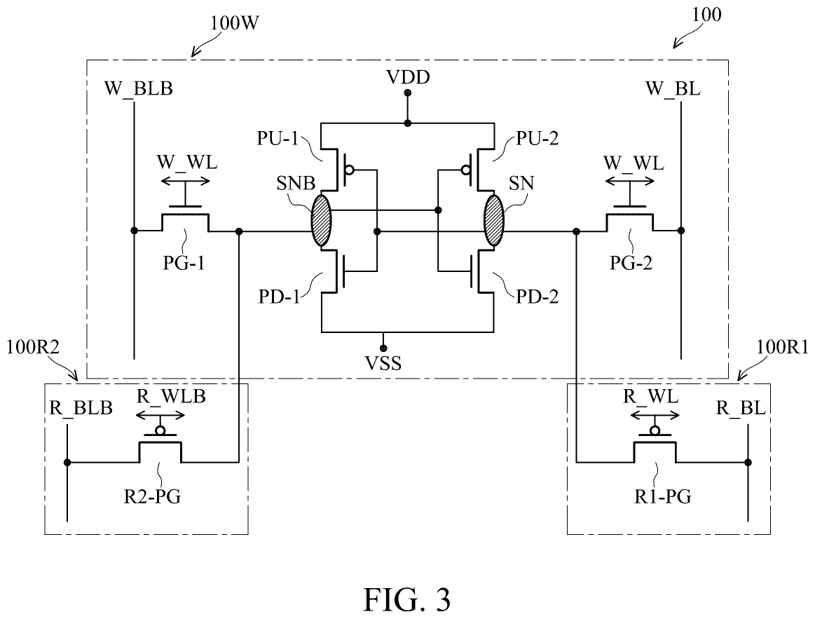

Referring now to FIG. 3, an example circuit schematic for a two-port SRAM cell 100 is shown. The two-port SRAM cell 100 includes a write-port 100W, a first read-port 100R1, and a second read-port 100R2. The write-port 100W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power voltage VDD (also referred to as VCC), and the sources of the pull-down transistors PD-1 and PD-2 are coupled to a voltage VSS, which may be an electrical ground in some embodiments.

The storage node SN of the data latch is coupled to a bit line W_BL of the write-port 100W through the pass-gate transistor PG-2, and the complementary storage node SNB is coupled to a complementary bit line W_BLB of the write-port 100W through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write-port 100W.

The first read-port 100R1 of the SRAM cell 100 includes a first read-port pass-gate transistor (R1-PG) coupled between the bit line R_BL and the storage node SN (or to the gates of the transistors PU-1 and PD-1). The gate of the first read-port pass-gate transistor R1-PG is coupled to a word line R_WL of the first read-port 100R1. The second read-port 100R2 of the SRAM cell 100 includes a second read-port pass-gate transistor (R2-PG) coupled between the complementary bit line R_BLB and the complementary storage node SNB (or to the gates of the transistors PU-2 and PD-2). The gate of the second read-port pass-gate transistor R2-PG is coupled to a complementary word line R_WLB of the second read-port 100R2. In the illustrated embodiment, the transistors R1-PG and R2-PG are p-type transistors. That is, in the two-port SRAM cell 100, the pass-gate transistors in a write-port are n-type transistors, and the pass-gate transistors in read-ports are p-type transistors.

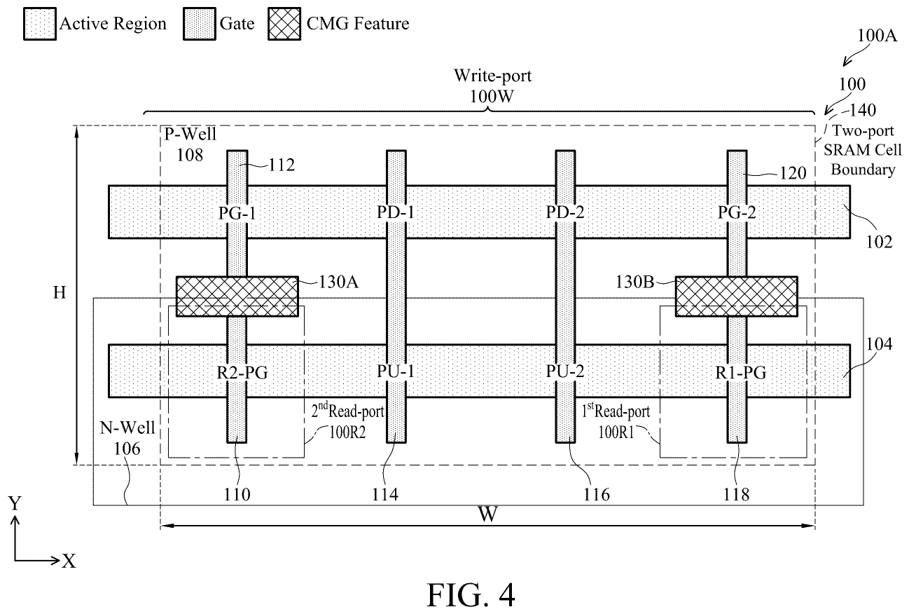

FIG. 4 illustrates a simplified diagrammatic layout 100A at the device layer (DL) of the two-port SRAM cell 100, which includes the write-port 100W, the first read-port 100R1, and the second read-port 100R2. The write-port 100W includes the transistors PG-1, PG-2, PU-1, PU-2, PD-1, and PD-2. The first read-port 100R1 includes the transistor R1-PG. The second read-port 100R2 includes the transistor R2-PG. For reasons of visual clarity and simplicity, the active regions and the gate structures of these transistors, together with some gate-cut features, are shown in FIG. 4, while the interconnection components such as contacts, vias, and metal lines are omitted from FIG. 4.

As shown in FIG. 4, the two-port SRAM cell 100 includes active regions 102 and 104. The active regions 102, 104 each extend lengthwise in the X-direction in FIG. 4. In the illustrated embodiment, the active regions 102, 104 may each include (or may be implemented as) the nanostructures 26 of FIG. 2 discussed above. In other embodiments, the active regions 102, 104 may include fin structures as well. The active region 102 are a components of the write-port 100W, and the active region 104 has a side portion as a component of the first read-port 100R1, a middle portion as a component of the write-port 100W, and another side portion as a component of the second read-port 100R2. In other words, the active region 104 is shared by the two read-ports 100R1, 100R2 and the write-port 100W. In the illustrated embodiment, the active region 104 belong to the transistors PU-1, PU-2, R1-PG, R2-PG, which are PMOS devices. As such, the active region 104 is formed over an N-well 106. Meanwhile, the active region 102 belongs to the transistors PG-1, PD-1, PD-2, PG-2, which are NMOS devices. As such, the active region 102 is formed over a P-well 108 (or a P-type substrate).

As shown in FIG. 4, the two-port SRAM cell 100 further includes gate structures 110, 112, 114, 116, 118, and 120. The gate structures 110-120 each extend lengthwise in the Y-direction in FIG. 4. The gate structures 110-120 may each include (or may be implemented as) the gate structures 20 of FIG. 2 discussed above. Each of the gate structures 110-120 has a critical dimension (CD) or gate width denoted as G. In the illustrated embodiment, the gate structures 110-120 are evenly distributed along the X-direction. An edge-to-edge (or center-to-center) distance between two adjacent gate structures along the X-direction is a poly pitch denoted as P. The gate structures 112, 114, 116, and 120 are components of the write-port 100W. The gate structure 118 is a component of the first read-port 100R1. The gate structure 110 is a component of the second read-port 100R2. The gate structures 114, 116 each extend through the two active regions 102, 104. As such, the gate structure 114 is shared by the transistors PD-1 and PU-1, and the gate structure 116 is shared by the transistors PD-2 and PU-2.

Still referring to FIG. 4, the two-port SRAM cell 100 further includes a plurality of gate-cut dielectric features extending lengthwise along the X-direction, including dielectric features 130A, 130B (collectively, dielectric features 130). In the illustrated embodiment, the dielectric feature 130A is disposed between the active regions 102, 104 and abuts the gate structure 110 and the gate structure 112. The dielectric feature 130A divides an otherwise continuous gate structure into two isolated segments corresponding to the gate structure 110 and the gate structure 112. Similarly, the dielectric feature 130B is disposed between the active regions 102, 104 and abuts the gate structure 118 and the gate structure 120. The dielectric feature 130B divides an otherwise continuous gate structure into two isolated segments corresponding to the gate structure 118 and the gate structure 120. Each of the dielectric features 130 is formed by filling a corresponding cut-metal-gate (CMG) trench in the position of the dielectric features. The dielectric features 130 are also referred to as CMG features. In the illustrated embodiment, each of the dielectric features 130A, 130B is disposed above an interface between the N-well 106 and the P-well 108.

A CMG process refers to a fabrication process where after a metal gate (e.g., a high-k metal gate or HKMG) replaces a dummy gate structure (e.g., a polysilicon gate), the metal gate is cut (e.g., by an etching process) to separate the metal gate into two or more gate segments. Each gate segment functions as a metal gate for an individual transistor. An isolation material is subsequently filled into trenches between adjacent portions of the metal gate. These trenches are referred to as cut-metal-gate trenches, or CMG trenches, in the present disclosure. The dielectric material filling a CMG trench for isolation is referred to as a CMG feature. To ensure a metal gate would be completely cut, a CMG feature often further extends into adjacent areas, such as dielectric layers filling space between the metal gates. A CMG feature often have an elongated shape in a top view.

Still referring to FIG. 4, a boundary 140 of the two-port SRAM cell 100 is illustrated in FIG. 4 using broken lines. Note that some of the active regions and gate structures may extend beyond the illustrated boundary 140, since these active regions and gate structures may also form components of other adjacently located SRAM cells as well. The boundary 140 is longer in the X-direction than in the Y-direction. In other words, the boundary 140 may be rectangular. The first dimension of the boundary 140 along the X-direction is denoted as a cell width W, and the second dimension of the boundary 140 along the Y-direction is denoted as a cell height H. Where the two-port SRAM cell 100 is repeated in a memory array, the cell width W may represent and be referred to as a memory cell pitch in the memory array along the X-direction, and the cell height H may represent and be referred to as a memory cell pitch in the memory array along the Y-direction.

The cell size of the two-port SRAM cell 100 is W×H, in which the cell width W is about 4 times a poly pitch (an edge-to-edge distance or center-to-center distance between two adjacent gate structures along the X-direction) and the cell height H is about 2 times an isolation pitch (e.g., a center-to-center distance between two adjacent STI features along the Y-direction). Denoting an area of one poly pitch times one isolation pitch as a unit area, each unit area includes an intersection of a gate structure and an active region, and the two-port SRAM cell 100 utilizes a cell size of about 8 times a unit area in accommodating the eight transistors, namely the transistors PG-1, PG-2, PU-1, PU-2, PD-1, PD-2, R1-PG, and R2-PG. The area utilization rate is high in the layout 100A, because each transistor formed at an intersection of a gate structure and an active region is a functional transistor and there is no non-functional transistor in the layout 100A.

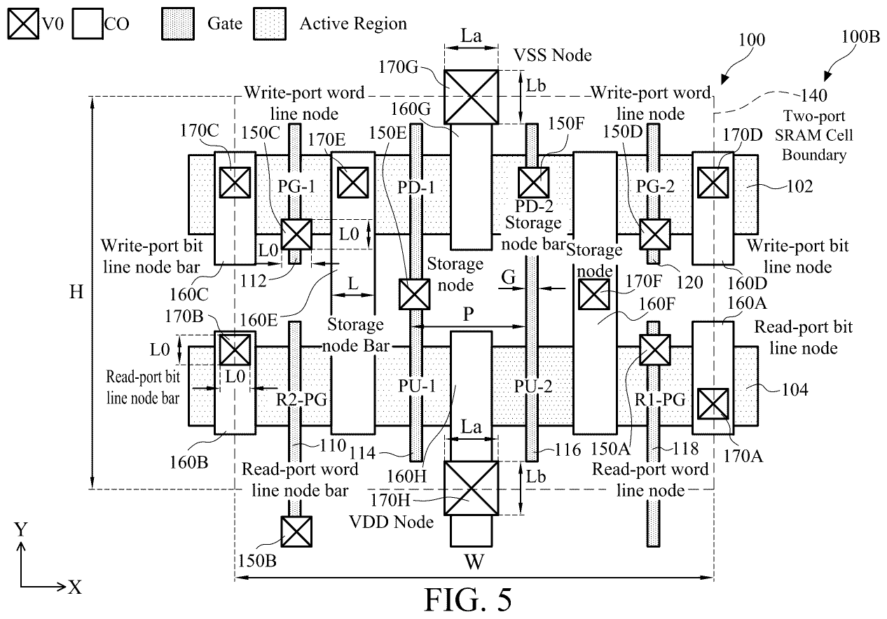

FIG. 5 illustrates a simplified diagrammatic layout 100B at the contact level (CO) and the via zero (V0) level of the two-port SRAM cell 100. Also, for reasons of aiding visual clarity, some features in the layout 100A devoted to the device layer (DL) are reproduced in FIG. 5, such as the active regions 102, 104, the gate structures 110-120, and the cell boundary 140, while numerous other features are omitted in FIG. 5.

A gate contact 150A electrically connects a gate of the first read-port pass-gate transistor R1-PG (formed by the gate structure 118) to the read-port word line R_WL. A gate contact 150B electrically connects a gate of the second read-port pass-gate transistor R2-PG (formed by the gate structure 110) to the read-port complementary word line R_WLB. A gate contact 150C electrically connects a gate of the write-port pass-gate transistor PG-1 (formed by the gate structure 112) to the write-port word line W_WL. A gate contact 150D electrically connects a gate of the write-port pass-gate transistor PG-2 (formed by the gate structure 120) to the write-port word line W_WL. A gate contact 150E electrically connects a gate of the write-port pull-down transistor PD-1 (formed by the gate structure 114) and a gate of the write-port pull-up transistor PU-1 (also formed by the gate structure 114) to the storage node SN. A gate contact 150F electrically connects a gate of the write-port pull-down transistor PD-2 (formed by the gate structure 116) and a gate of the write-port pull-up transistor PU-2 (also formed by the gate structure 116) to the complementary storage node SNB.

A source/drain contact 160A and a source/drain contact via 170A landing thereon electrically connect a source region of the first read-port pass-gate transistor R1-PG to the read-port bit line R_BL. A source/drain contact 160B and a source/drain contact via 170B landing thereon electrically connect a source region of the second read-port pass-gate transistor R2-PG to the read-port complementary bit line R_BLB. A source/drain contact 160C and a source/drain contact via 170C landing thereon electrically connect a source region of the write-port pass-gate transistor PG-1 to the write-port complementary bit line W_BLB. A source/drain contact 160D and a source/drain contact via 170D landing thereon electrically connect a source region of the write-port pass-gate transistor PG-2 to the write-port bit line W_BL. A source/drain contact 160E and a source/drain contact via 170E landing thereon electrically connect a common drain region of the write-port pass-gate transistor PG-1 and the write-port pull-down transistor PD-1 together with a common drain region of the write-port pull-up transistor PU-1 and the second read-port pass-gate transistor R2-PG to the complementary storage node SNB. A source/drain contact 160F and a source/drain contact via 170F landing thereon electrically connect a common drain region of the write-port pass-gate transistor PG-2 and the write-port pull-down transistor PD-2 together with a common drain region of the write-port pull-up transistor PU-2 and the first read-port pass-gate transistor R1-PG to the storage node SN. A source/drain contact 160G and a source/drain contact via 170G landing thereon electrically connect a common source region of the write-port pull-down transistor PD-1 and the write-port pull-down transistor PD-2 to the electrical ground node Vss. A source/drain contact 160H and a source/drain contact via 170H landing thereon electrically connect a common source region of the write-port pull-up transistor PU-1 and the write-port pull-up transistor PU-2 to the power voltage node V_{DD}. In the illustrated embodiment, the source/drain contacts 360A-360H each are elongated and have a longitudinal direction in the Y-direction, which is parallel to the extending directions of gate structures.

Still referring to FIG. 5, the gate contacts 150A-F and the source/drain contact vias 170A-F may have the same size in a top view. For example, each of the gate contacts 150A-F and the source/drain contact vias 170A-F may have a square shape with the same edge length LO in the X-direction and in the Y-direction. Further in the illustrated embodiment, each of the source/drain contacts 160A-H may have the same width L measured in the X-direction, and the edge length L0 may be smaller than the width L. As a comparison, each of the source/drain contact vias 170G and 170H has a larger size, such as a first dimension La measured in the X-direction and a second dimension Lb measured in the Y-direction with La>L0 and Lb>L0. Further, the first dimension La may be larger than the width L. The source/drain contact vias 170G and 170H are electrically connected to the electrical ground node and power voltage node, respectively, whose resistances contribute more impacts to an SRAM cell's speed than other source/drain contact vias and gate contacts. The larger size of the source/drain contact vias 170G and 170H reduces respective source/drain contact via resistance and effectively improves circuit speed. In some embodiments, a range of La/L0 is from about 1 to about 3, and a range of Lb/L0 is from about 1 to about 3. In some embodiments, a range of La/G is from about 1 to about 3, and a range of Lb/G is from about 1 to about 3. In some embodiments, a range of La/L is from about 1 to about 3, and a range of Lb/L is from about 1 to about 3. The larger source/drain contact vias 170G and 170H may have an extra barrier (and/or glue) layer than the smaller gate contacts 150A-F and the source/drain contact vias 170A-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 170G and 170H are depicted as having the same size in the illustrated embodiment, they may have different sizes to meet various performance needs. For example, the source/drain contact via 170G may have the same size as the gate contacts 150A-F and the source/drain contact vias 170A-F (e.g., a square shape with the edge length L0), while the source/drain contact via 170H may have the larger size (La and Lb) to reduce IR drop from a power voltage line. Alternatively, the source/drain contact via 170H may have the same size as the gate contacts 150A-F and the source/drain contact vias 170A-F (e.g., a square shape with the edge length L0), while the source/drain contact via 170G may have the larger size (La and Lb) to reduce ground bounce from an electrical ground line.

Also shown in FIG. 5, the storage node SN includes the gate contact 150E and the source/drain contact via 170F positioned on two opposing sides of the gate structure 116. As to discuss in further detail below, a metal line at the M0 level extends in the X-direction to across the gate structure 116 and connects the gate contact 150E and the source/drain contact via 170F. In other words, an M0 metal line hangs over the gate structure 116 and provide the function of cross coupling between the gate contact 150E and the source/drain contact via 170F. Therefore, in the layout 100B, the gate contact 150E and the source/drain contact via 170F are positioned as being level in the Y-direction, such that a metal line extending in the X-direction may connect both. Similarly, the complementary storage node (storage node bar) SNB includes the gate contact 150F and the source/drain contact via 170E positioned on two opposing sides of the gate structure 114. As to discuss in further detail below, another metal line at the MO level extends in the X-direction to across the gate structure 114 and connects the gate contact 150F and the source/drain contact via 170E. In other words, another M0 metal line hangs over the gate structure 114 and provide the function of cross coupling between the gate contact 150F and the source/drain contact via 170E. Therefore, in the layout 100B, the gate contact 150F and the source/drain contact via 170E are positioned as being level in the Y-direction, such that a metal line extending in the X-direction may connect both.

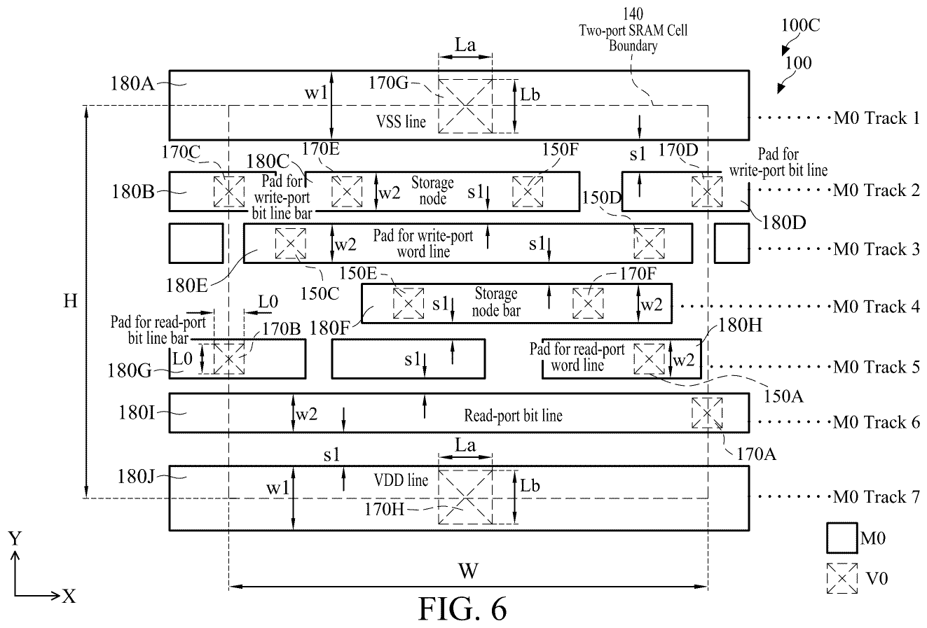

FIG. 6 illustrates a simplified diagrammatic layout 100C at the metal zero (M0) level of the two-port SRAM cell 100. Also, for reasons of aiding visual clarity, the gate contacts 150A-F and source/drain contact vias 170A-H at the via zero (V0) level are reproduced in FIG. 6, while numerous other features are omitted in FIG. 6.

At the M0 level, the SRAM cell 100 includes a plurality of metal tracks arranged in parallel. Particularly, in the illustrated embodiment of the layout 100C, the SRAM cell 100 includes seven metal tracks arranged in order from first (M0 Track 1) to seventh (M0 Track 7) along the Y-direction. The center lines of the metal tracks are represented by the dotted lines in FIG. 6. A distance between the center lines of the adjacent metal tracks is denoted as the metal track pitch.

One metal track may include a single metal line extending through the entire SRAM cell 100 along the X-direction. Such a metal line is denoted as a global metal line. Alternatively, one metal track may include one or more metal lines that do not extend through the entire SRAM cell 100. Such a metal line is denoted as a local metal line, or referred to as an island, a pad, or a landing pad. In the layout 100C, the first metal track “M0 Track 1” includes a global metal line 180A, which is a VSS line electrically coupled to the source/drain contact via 170G. The VSS line 180A is disposed on the upper boundary line of the SRAM cell 100 and shared with an adjacent SRAM cell. Disposed on the upper boundary line of the SRAM cell 100, the source/drain contact via 170G is also shared by the two adjacent SRAM cells. The second metal track “M0 Track 2” includes three local metal lines 180B, 180C, and 180D. The local metal line 180B provides a pad for the write-port complimentary bit line (W_BLB). The local metal line 180B extends beyond a left edge of the SRAM cell 100 and may be shared with an adjacent SRAM cell. The local metal line 180C is fully within the SRAM cell 100, which belongs to the storage node (SN) and provides cross-coupling between the gate contact 150F and the source/drain contact via 170E. As discussed above, the local metal line 180C crosses over the gate structure 114. The local metal line 180D provides a pad for the write-port bit line (W_BL). The local metal line 180D extends beyond a right edge of the SRAM cell 100 and may be shared with an adjacent SRAM cell. The third metal track “M0 Track 3” includes a local metal line 180E as a pad for the write-port word line (W_WL). The local metal line 180E is fully within the SRAM cell 100 and electrically connects to the gate contact 150C and the gate contact 150D. The fourth metal track “M0 Track 4” includes a local metal line 180F, which belongs to the complementary storage node (SNB). The local metal line 180F is fully within the SRAM cell 100 and provides cross-coupling between the gate contact 150E and the source/drain contact via 170F. As discussed above, the local metal line 180F crosses over the gate structure 116. The fifth metal track “M0 Track 5” includes a local metal line 180G and a local metal line 180H. The local metal line 180G provides a pad for the read-port complimentary bit line (R_BLB). The local metal line 180G extends beyond a left edge of the SRAM cell 100 and may be shared with an adjacent SRAM cell. The local metal line 180H provides a pad for the read-port word line (R_WL). The local metal line 180H extends beyond a right edge of the SRAM cell 100 and may be shared with an adjacent SRAM cell. There may be a non-functional (electrically floating) pad inserted between the local metal line 180G and the local metal line 180H for improving uniformity of metal line density. The sixth metal track “M0 Track 6” includes a global metal line 1801, which is a read-port bit line electrically coupled to the source/drain contact via 170A. The seventh metal track “M0 Track 7” includes a global metal line 180J, which is a VDD line electrically coupled to the source/drain contact via 170H. The VDD line 180J is disposed on the lower boundary line of the SRAM cell 100 and may be shared with an adjacent SRAM cell. Disposed on the lower boundary line of the SRAM cell 100, the source/drain contact via 170H is also shared by the two adjacent SRAM cells.

A width of the VSS line 180A is denoted as w1 with one half of w1 in one SRAM cell and another half of w1 in the adjacent SRAM cell. A width of the VDD line 180J may be substantially the same as the VSS line 180A with one half of w1 in one SRAM cell and another half of w1 in the adjacent SRAM cell. The other M0 metal lines 180B-180I may each have the same width denoted as w2. The spacing between two adjacent M0 metal lines may be uniform and denoted as s1. Thus, the SRAM cell height H equals w1+5*w2+6*s1. In the illustrated embodiment, the second dimension Lb of the larger source/drain contact vias 170G and 170H is smaller than the width w1 of the respective VSS line 180A and VDD line 180J (Lb<w1). Alternatively, the second dimension Lb of the larger source/drain contact vias 170G and 170H may equal the width w1 of the respective VSS line 180A and VDD line 180J (Lb=w1) to increase contact area and reduce contact resistance.

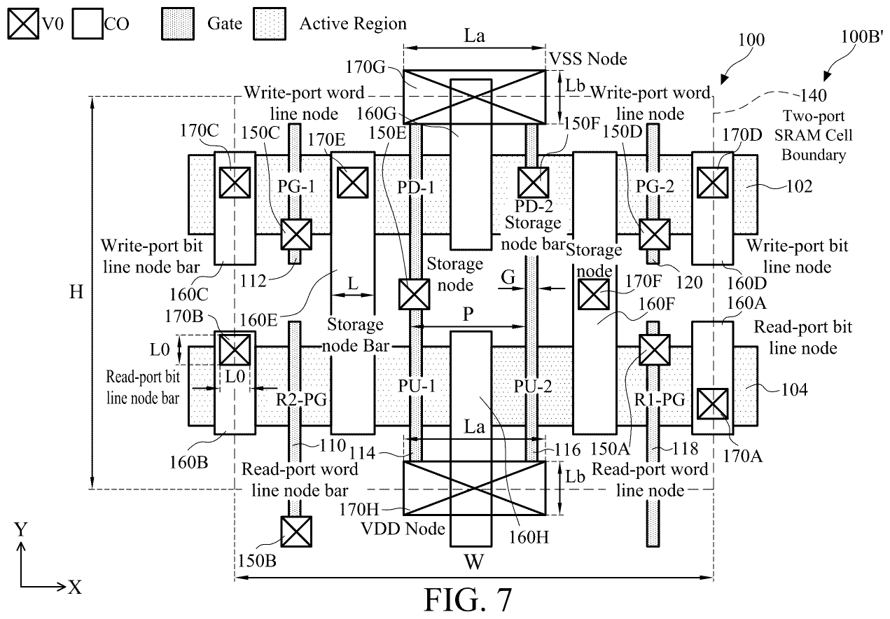

FIG. 7 illustrates an alternative diagrammatic layout 100B′ at the contact level (CO) and the via zero (V0) level of the two-port SRAM cell 100. Also, for reasons of aiding visual clarity, some features in the layout 100A devoted to the device layer (DL) are reproduced in FIG. 7, such as the active regions 102, 104, the gate structures 110-120, and the cell boundary 140, while numerous other features are omitted in FIG. 7. The gate contacts 150A-F and the source/drain contact vias 170A-F in the layout 100B′ may be substantially similar with the counterparts in the layout 100B. One difference is that the source/drain contact vias 170G and 170H in the layout 100B′ may be further enlarged to further reduce contact via resistance. For example, edges of the source/drain contact vias 170G and 170H may extend beyond outer edges of the gate structure 114 and the gate structure 116. State differently, the first dimension La may be larger than a sum of the poly pitch P and the gate width G (La>P+G). In furtherance of the embodiment, a portion of the gate structure 114 and a portion of the gate structure 116 may be directly under the source/drain contact vias 170G and 170H. In some embodiments, a range of La/L0 is from about 1 to about 5, and a range of Lb/L0 is from about 1 to about 5. In some embodiments, a range of La/G is from about 1 to about 5, and a range of Lb/G is from about 1 to about 5. In some embodiments, a range of La/L is from about 1 to about 5, and a range of Lb/L is from about 1 to about 5. In some embodiments, Lb may be smaller than or equal to the width w1 (Lb≤w1) of the VSS line and VDD line in the M0 level (FIG. 6).

Similar to the discussion above, the larger source/drain contact vias 170G and 170H may have an extra barrier (and/or glue) layer than the smaller gate contacts 150A-F and the source/drain contact vias 170A-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 170G and 170H are depicted as having the same size in the illustrated embodiment, they may have different sizes to meet various performance needs. For example, the source/drain contact via 170G may have the same size as the gate contacts 150A-F and the source/drain contact vias 170A-F (e.g., a square shape with the edge length L0), while the source/drain contact via 170H may have the larger size (La and Lb) to reduce IR drop from a power voltage line. Alternatively, the source/drain contact via 170H may have the same size as the gate contacts 150A-F and the source/drain contact vias 170A-F (e.g., a square shape with the edge length L0), while the source/drain contact via 170G may have the larger size (La and Lb) to reduce ground bounce from an electrical ground line.

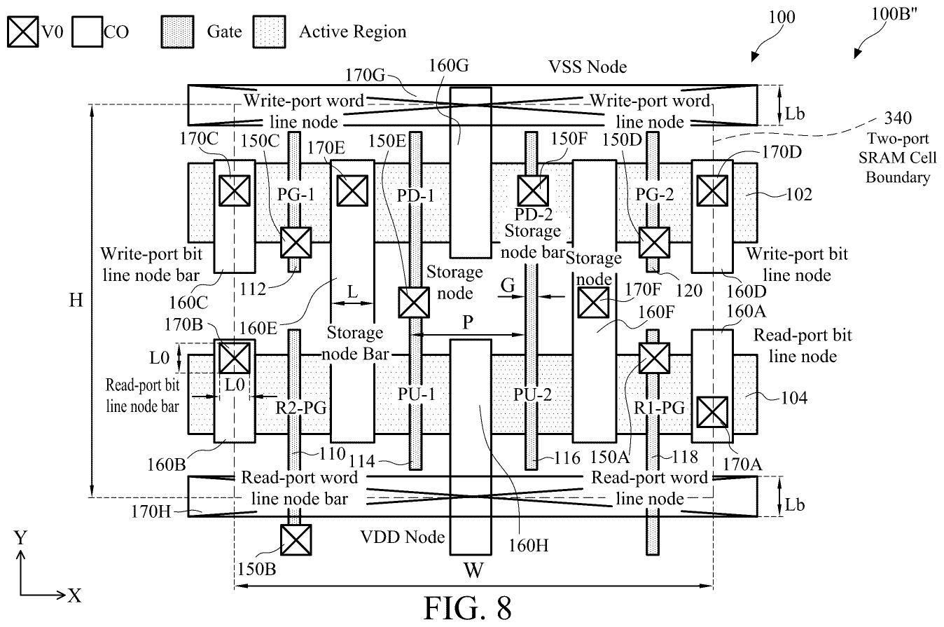

FIG. 8 illustrates an alternative diagrammatic layout 100B″ at the contact level (CO) and the via zero (V0) level of the two-port SRAM cell 100. Also, for reasons of aiding visual clarity, some features in the layout 100A devoted to the device layer (DL) are reproduced in FIG. 8, such as the active regions 102, 104, the gate structures 110-120, and the cell boundary 140, while numerous other features are omitted in FIG. 8. The gate contacts 150A-F and the source/drain contact vias 170A-F in the layout 100B″ may be substantially similar with the counterparts in the layout 100B′. One difference is that the source/drain contact vias 170G and 170H in the layout 100B′ may be further enlarged to further reduce contact via resistance. For example, the source/drain contact vias 170G and 170H may have a form of a rail that extends through the cell boundary 140 in the X-direction. The second dimension Lb of the source/drain contact vias 170G and 170H may be larger, or alternatively smaller, than the edge length L0 of other source/drain contact vias and gate contacts. In some embodiments, a range of Lb/L0 is from about 0.3 to about 5. In some embodiments, a range of Lb/G is from about 0.3 to about 5. In some embodiments, a range of Lb/L is from about 0.3 to about 5. In some embodiments, Lb may be smaller than or equal to the width w1 (Lb≤w1) of the VSS line and VDD line in the M0 level (FIG. 6).

Similar to the discussion above, the larger source/drain contact vias 170G and 170H may have an extra barrier (and/or glue) layer than the smaller gate contacts 150A-F and the source/drain contact vias 170A-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 170G and 170H are depicted as having the same size in the illustrated embodiment, they may have different sizes to meet various performance needs. For example, the source/drain contact via 170G may have the same size as the gate contacts 150A-F and the source/drain contact vias 170A-F (e.g., a square shape with the edge length L0), while the source/drain contact via 170H may have the larger size to reduce IR drop from a power voltage line. Alternatively, the source/drain contact via 170H may have the same size as the gate contacts 150A-F and the source/drain contact vias 170A-F (e.g., a square shape with the edge length L0), while the source/drain contact via 170G may have the larger size to reduce ground bounce from an electrical ground line.

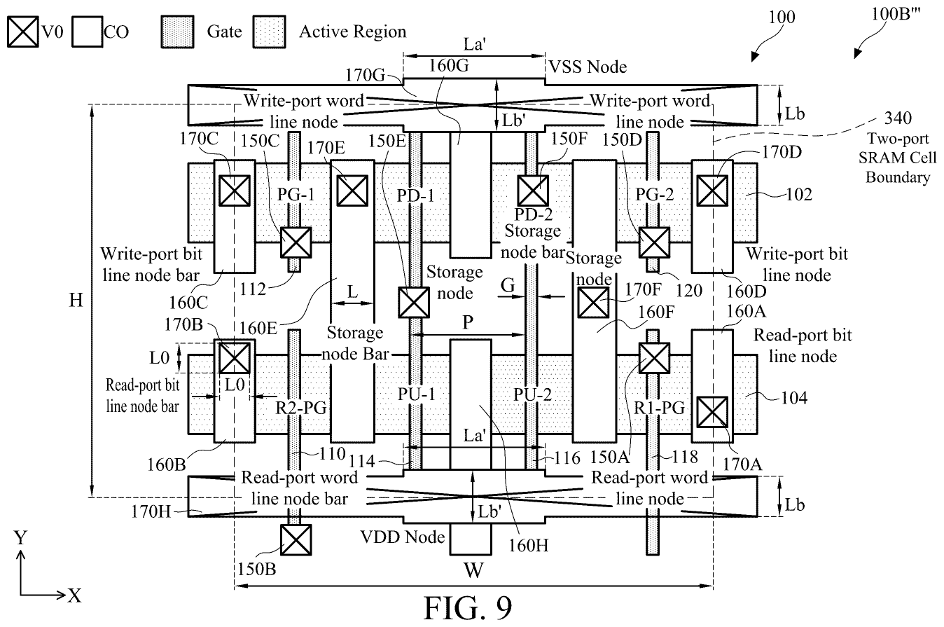

FIG. 9 illustrates an alternative diagrammatic layout 100B′″ at the contact level (CO) and the via zero (V0) level of the two-port SRAM cell 100. Also, for reasons of aiding visual clarity, some features in the layout 100A devoted to the device layer (DL) are reproduced in FIG. 9, such as the active regions 102, 104, the gate structures 110-120, and the cell boundary 140, while numerous other features are omitted in FIG. 9. The gate contacts 150A-F and the source/drain contact vias 170A-F in the layout 100B′″ may be substantially similar with the counterparts in the layout 100B″. One difference is that the source/drain contact vias 170G and 170H in the layout 100B″ may be further enlarged to further reduce contact via resistance. For example, the source/drain contact vias 170G and 170H may have a form of a rail that extends through the cell boundary 140 in the X-direction and a jog portion overlaying the respective source/drain contacts 160G and 160H. The jog portion has a first dimension La′ and a larger second dimension Lb′ (Lb′>Lb). In some embodiments, a range of Lb′/Lb is from about 1 to about 3. Edges of the jog portion of the source/drain contact vias 170G and 170H may extend beyond outer edges of the gate structure 114 and the gate structure 116. State differently, the first dimension La′ of the jog portion may be larger than a sum of the poly pitch P and the gate width G (La>P+G). In furtherance of the embodiment, a portion of the gate structure 114 and a portion of the gate structure 116 may be directly under the jog portion of the source/drain contact vias 170G and 170H. In some embodiments, a range of Lb/L0 is from about 0.3 to about 5. In some embodiments, a range of Lb/G is from about 0.3 to about 5. In some embodiments, a range of Lb/L is from about 0.3 to about 5. In some embodiments, Lb′ may be smaller than or equal to the width w1 (Lb<Lb′≤w1) of the VSS line and VDD line in the M0 level (FIG. 6).

Similar to the discussion above, the larger source/drain contact vias 170G and 170H may have an extra barrier (and/or glue) layer than the smaller gate contacts 150A-F and the source/drain contact vias 170A-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 170G and 170H are depicted as having the same size in the illustrated embodiment, they may have different sizes to meet various performance needs. For example, the source/drain contact via 170G may have the same size as the gate contacts 150A-F and the source/drain contact vias 170A-F (e.g., a square shape with the edge length L0), while the source/drain contact via 170H may have the larger size to reduce IR drop from a power voltage line. Alternatively, the source/drain contact via 170H may have the same size as the gate contacts 150A-F and the source/drain contact vias 170A-F (e.g., a square shape with the edge length L0), while the source/drain contact via 170G may have the larger size to reduce ground bounce from an electrical ground line.

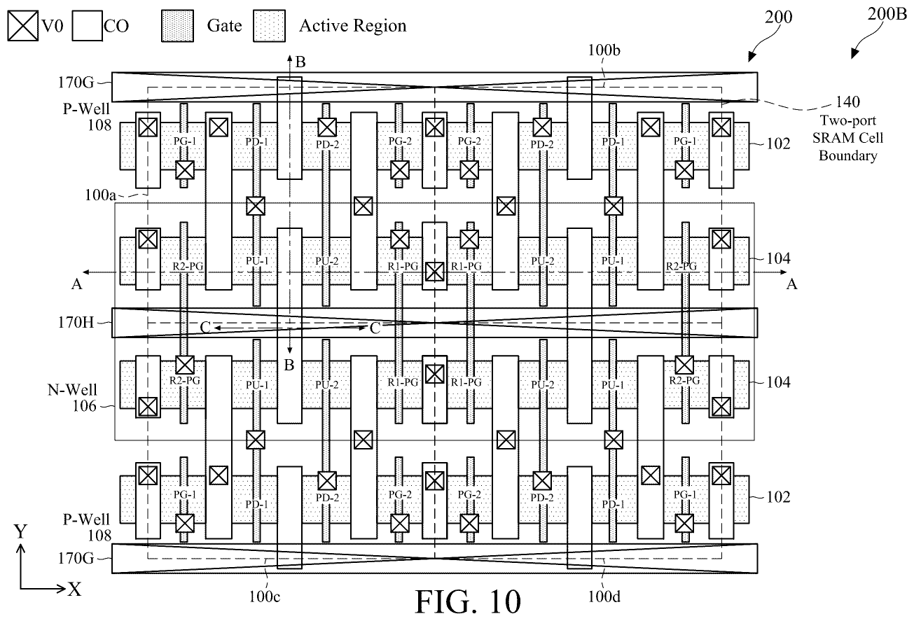

FIG. 10 illustrates a diagrammatic layout 200B of an SRAM array 200 according to the present disclosure. Referring to FIG. 10, a plurality of two-port SRAM cells 100a, 100b, 100c, and 100d are arranged in the X-direction and the Y-direction, forming a 2×2 array of SRAM cells. Each SRAM cell in the array may use the layout of the SRAM cell 100 as depicted in FIG. 4. In some embodiments, two adjacent SRAM cells in the X-direction are line symmetric with respect to a common boundary therebetween, and two adjacent SRAM cells in the Y-direction are line symmetric with respect to a common boundary therebetween. That is, the SRAM cell 100b is a duplicate cell for the SRAM cell 100a but flipped over the Y-axis; the SRAM cell 100c is a duplicate cell for the SRAM cell 100a but flipped over the X-axis; and the SRAM cell 100d is a duplicate cell for the SRAM cell 100b but flipped over the X-axis. FIG. 10 has been simplified for the sake of clarity to better understand the inventive concepts of the present disclosure. For example, active regions, gate structures, gate contacts, source/drain contacts, source/drain contact vias, N-well, P-well, and cell boundaries for shown, while some other features are omitted in FIG. 10.

The SRAM array 200 includes well regions 106 and 108 alternately arranged along the Y-axis. In other words, every P-well region 108 is next to an N-well region 106 which is next to another P-well region 108, and this pattern repeats. In the illustrated embodiment as in FIG. 8, some gate structures may be shared by neighboring SRAM cells, such that these gate structures extend lengthwise across the boundary between neighboring SRAM cells. For example, the transistor R2-PG in the SRAM cell 100a and the transistor R2-PG in the SRAM cell 100c share the same gate structure, which extends lengthwise across the boundary between the SRAM cells 100a and 100c; the transistor R1-PG in the SRAM cell 100a and the transistor R1-PG in the SRAM cell 100c shares the same gate structure, which extends lengthwise across the boundary between the SRAM cells 100a and 100c; the transistor R1-PG in the SRAM cell 100b and the transistor R1-PG in the SRAM cell 100d shares the same gate structure, which extends lengthwise across the boundary between the SRAM cells 100b and 100d; and the transistor R2-PG in the SRAM cell 100b and the transistor R2-PG in the SRAM cell 100d shares the same gate structure, which extends lengthwise across the boundary between the SRAM cells 100b and 100d.

In the depicted embodiment, the source/drain contact vias 170G and 170H are in the form of a rail as depicted in FIG. 8. Alternatively, the source/drain contact vias 170G and 170H may be in the form of a patch as depicted in FIGS. 5 and 6, or in the form of a rail with a jog portion as depicted in FIG. 9. Each of the source/drain contact vias 170G and 170H is shared by adjacent SRAM cells. For example, the source/drain contact via 170H, which is electrically coupled to the power voltage VDD, is positioned between two P-type active regions (over the N-well 106) and shared by the SRAM cells 100a, 100b, 100c, and 100d. Similarly, the source/drain contact via 170G, which is electrically coupled to the electrical ground VSS, is positioned between two N-type active regions (over the P-well 108) and shared by the adjacent four SRAM cells.

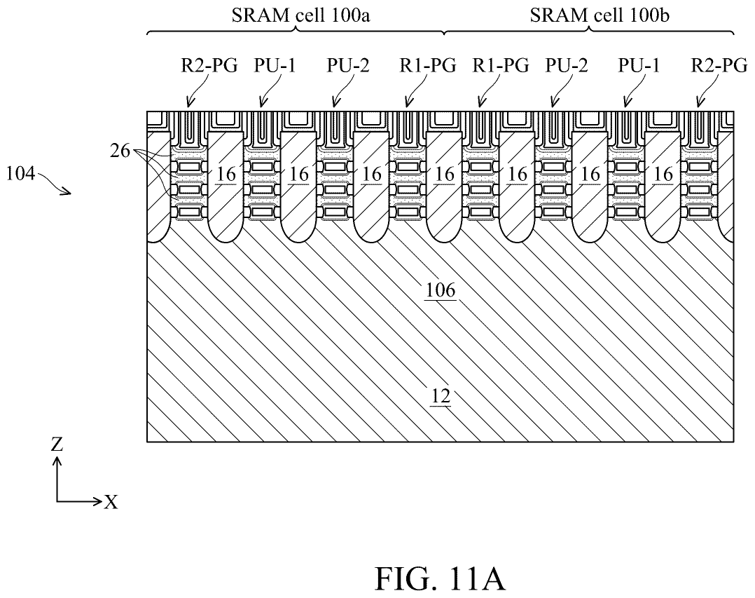

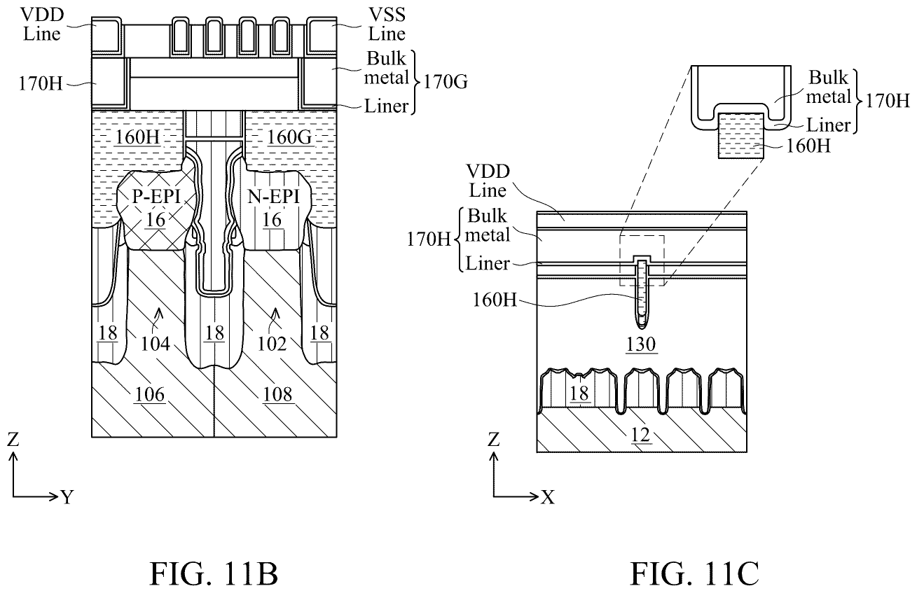

FIG. 11A is a fragmentary diagrammatic cross-sectional view along A-A line of FIG. 10, which cuts the active region 104 along its lengthwise direction, according to various aspects of the present disclosure. FIG. 11B is a fragmentary diagrammatic cross-sectional view along B-B line of FIG. 10, which cuts source/drain regions along a middle line of the SRAM cell 100a, according to various aspects of the present disclosure. FIG. 11C is a fragmentary diagrammatic cross-sectional view along C-C line of FIG. 10, which cuts the source/drain contact via 170H along a boundary line between the SRAM cells 100a and 100c, according to various aspects of the present disclosure.

Referring to FIGS. 11A-C collectively, the active region 104 extends continuously through the SRAM cells 100a, 100b (and other SRAM cells in the same row of the array 180). The active region 104 includes channel regions that is comprised of the nanostructures 26 and source/drain features 16 abut the ends of the nanostructures 26. The gate structures wrap around the nanostructures 26 and form the transistors R2-PG, PU-1, PU-2, R1-PG in the SRAM cell 100a and the transistors R1-PG, PU-2, PU-1, R2-PG in the SRAM cell 100b. The active region 104 is disposed over the N-well 106, and the active region 102 is disposed over the P-well 108. The source/drain features 16 formed on the active region 104 is p-type epitaxial features, and the source/drain features 16 formed on the active region 102 is n-type epitaxial features. The source/drain contact 160H electrically connects to the source/drain features 16 formed on the active region 104, and the source/drain contact 160G electrically connects to the source/drain features 16 formed on the active region 102. The source/drain contact via 170H is sandwiched between the source/drain contact 160H and the VDD line in the M0 level, and the source/drain contact via 170G is sandwiched between the source/drain contact 160G and the VSS line in the M0 level. Due to the larger size of the source/drain contact vias 170H and 170G, a liner (such as a compound of Ti/TiN) may function as a barrier layer and/or a glue layer in surrounding a bulk metal (e.g., tungsten). As a comparison, gate contacts and other source/drain contact vias may include the bulk metal but free of the liner. FIG. 11C illustrates the source/drain contact via 170H in the form of a rail extending parallel with the VDD line or alternatively as a patch in the region circled by the broken line. In either form, a bottom surface of the source/drain contact via 170H is larger than the source/drain contact 160H, such that an etching process during the formation of the source/drain contact via 170H may extend the bottom surface of the source/drain contact via 170H below a top surface of the source/drain contact 160H, such as for a vertical distance of 1 nm to about 4 nm. In other words, the top portion of the source/drain contact 160H may be partially embedded in the bottom portion of the source/drain contact via 170H for a vertical distance of 1 nm to about 4 nm.

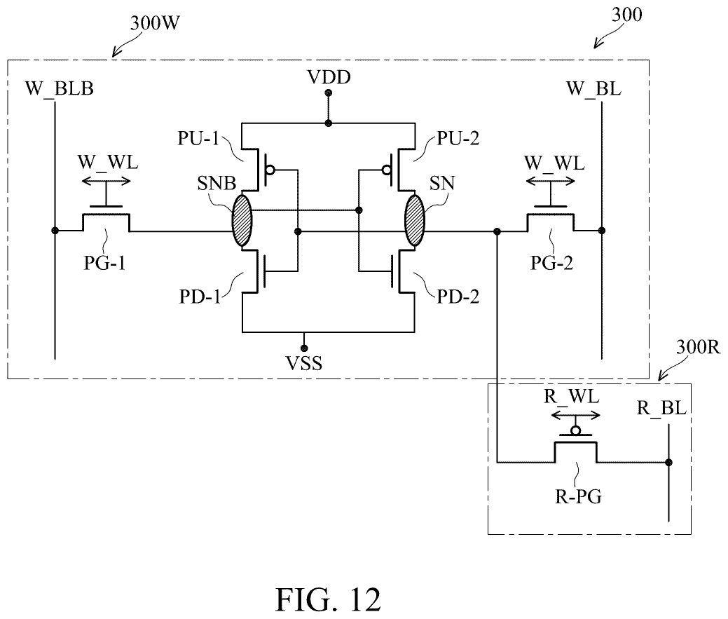

Referring now to FIG. 12, an example circuit schematic for a two-port SRAM cell 300 is shown. The two-port SRAM cell 300 includes a write-port 300W and a read-port 300R. The write-port 300W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power voltage VDD (also referred to as VCC), and the sources of the pull-down transistors PD-1 and PD-2 are coupled to a voltage VSS, which may be an electrical ground in some embodiments.

The storage node SN of the data latch is coupled to a bit line W_BL of the write-port 100W through the pass-gate transistor PG-2, and the complementary storage node SNB is coupled to a complementary bit line W_BLB of the write-port 100W through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write-port 100W.

The read-port 300R of the SRAM cell 300 includes a read-port pass-gate transistor (R-PG) coupled between the bit line R_BL and the storage node SN (or to the gates of the transistors PU-1 and PD-1). The gate of the read-port pass-gate transistor R-PG is coupled to a word line R_WL of the read-port 300R. In the illustrated embodiment, the transistor R-PG is a p-type transistor. That is, in the two-port SRAM cell 300, the pass-gate transistors in a write-port are n-type transistors, and the pass-gate transistor in a read-port is a p-type transistor.

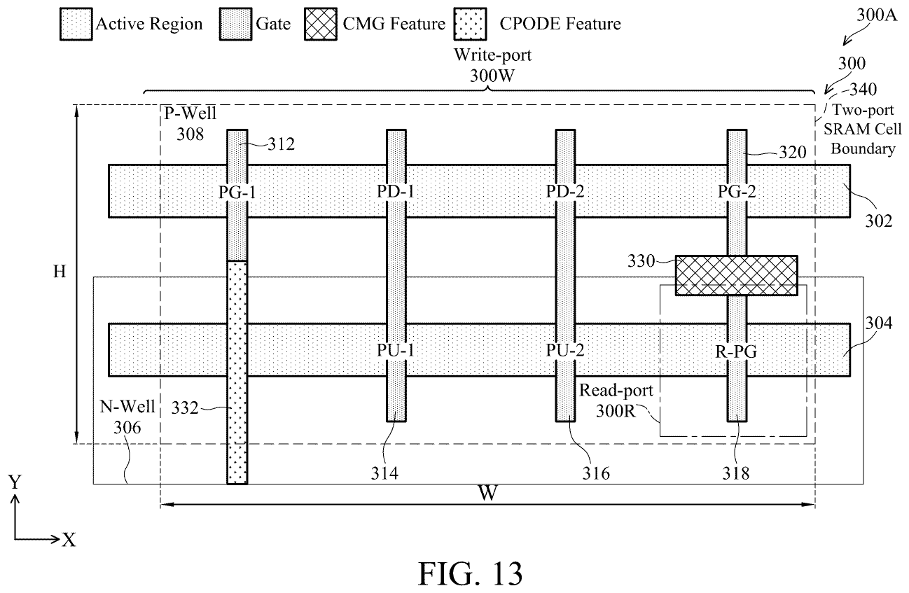

FIG. 13 illustrates a simplified diagrammatic layout 300A of the device layer (DL) of the two-port SRAM cell 300, which includes the write-port 300W and the read-port 300R. The write-port 300W includes the transistors PG-1, PG-2, PU-1, PU-2, PD-1, and PD-2. The read-port 300R includes the transistor R-PG. For reasons of visual clarity and simplicity, the layout 300A includes active regions and gate structures of those transistors in the SRAM cell 300, together with some gate-cut features, while numerous other features in or above the device layer DL such as contacts, vias, and metal lines are not included in the layout 300A.

As shown in FIG. 13, the two-port SRAM cell 300 includes active regions 302 and 304. The active regions 302, 304 each extend lengthwise in the X-direction in FIG. 13. In the illustrated embodiment, the active regions 302, 304 may each include (or may be implemented as) the nanostructures 26 of FIG. 2 discussed above. In other embodiments, the active regions 302, 304 may include fin structures as well. The active region 302 are a components of the write-port 300W, and the active region 304 has a side portion as a component of the read-port 300R and rest portion as a component of the write-port 300W. In other words, the active region 304 is shared by the read-port 300R and the write-port 300W. In the illustrated embodiment, the active region 304 belong to the transistors PU-1, PU-2, R-PG, which are PMOS devices. As such, the active region 304 is formed over an n-well 306. Meanwhile, the active region 302 belongs to the transistors PG-1, PD-1, PD-2, PG-2, which are NMOS devices. As such, the active region 302 is formed over a p-well 308 (or a p-type substrate).

As shown in FIG. 13, the two-port SRAM cell 100 further includes gate structures 312, 314, 316, 318, and 320. The gate structures 312-320 each extend lengthwise in the Y-direction in FIG. 13. The gate structures 312-320 may each include (or may be implemented as) the gate structures 20 of FIG. 2 discussed above. Each of the gate structures 312-320 has a critical dimension (CD) or gate width denoted as G. In the illustrated embodiment, the gate structures 312-320 are evenly distributed along the X-direction. An edge-to-edge (or center-to-center) distance between two adjacent gate structures along the X-direction is a poly pitch denoted as P. The gate structures 312, 314, 316, and 320 are components of the write-port 300W. The gate structure 318 is a component of the read-port 300R. The gate structures 314, 316 each extend through the two active regions 302, 304. As such, the gate structure 314 is shared by the transistors PD-1 and PU-1, and the gate structure 316 is shared by the transistors PD-2 and PU-2.

Still referring to FIG. 13, the two-port SRAM cell 300 further includes a plurality of gate-cut dielectric features, including a first dielectric feature 330 extending lengthwise along the X-direction and a second dielectric feature 332 extending lengthwise along the Y-direction. In the illustrated embodiment, the dielectric feature 330 is disposed between the active regions 302, 304 and abuts the gate structure 318 and the gate structure 320. The dielectric feature 330 divides an otherwise continuous gate structure line into two isolated segments corresponding to the gate structure 318 and the gate structure 320. The dielectric feature 330 is formed by filling a corresponding cut-metal-gate (CMG) trench in the position of the dielectric feature 330. The dielectric feature 330 is also referred to as a CMG feature. In the illustrated embodiment, the dielectric feature 330 is disposed above an interface between the n-well 306 and the p-well 308.

The gate-cut feature 332 is formed in a continuous-poly-on-diffusion-edge (CPODE) process and also referred to as a CPODE feature. For purposes of this disclosure, a “diffusion edge” may be equivalently referred to as an active edge, where for example an active edge abuts adjacent active regions. Before the CPODE process, the active edge may include a dummy GAA structure having a dummy gate structure (e.g., a polysilicon gate) and a plurality of vertically stacked nanostructures as channel layers. In addition, inner spacers may be disposed between adjacent nanostructures at lateral ends of the nanostructures. In various examples, source/drain epitaxial features are disposed on either side of the dummy GAA structure, such that the adjacent source/drain epitaxial features are in contact with the inner spacers and nanostructures of the dummy GAA structure. The subsequent CPODE etching process removes the dummy gate structure and the channel layers from the dummy GAA structure to form a CPODE trench. The dielectric material filling a CPODE trench for isolation is referred to as a CPODE feature. In some embodiments, after the CPODE features are formed, the remaining dummy gate structures are replaced by metal gate structures in a replacement gate (gate-last) process. State differently, in some embodiments, the CPODE feature replaces a portion of the otherwise continuous gate structure and is confined between the opposing gate spacers of the replaced portion of the gate structure. As a comparison, the CMG feature is formed after the formation of the metal gate structure line and truncates the otherwise continuous gate structure line and extends into adjacent areas of the gate structure, while the CPODE feature is formed after the formation of the polysilicon gate structure line and prior to the formation of the metal gate structure and extends aligned with the metal gate structure. In FIG. 13, the CPODE feature 332 abuts the gate structure 312 and is aligned with the gate structure 312. The CPODE feature 332 extends along the Y-direction and across the n-well 306 into another p-well 308 of an adjacent SRAM cell. That is, two adjacent SRAM cells may share the CPODE feature 332. Further, the CPODE feature 332 may extend downwardly deeper into the underneath substrate than the CMG feature 130, in some embodiments.

Still referring to FIG. 13, a boundary 340 of the two-port SRAM cell 300 is illustrated in FIG. 13 using broken lines. Note that some of the active regions and gate structures may extend beyond the illustrated boundary 340, since these active regions and gate structures may also form components of other adjacently located SRAM cells as well. The boundary 340 is longer in the X-direction than in the Y-direction. In other words, the boundary 340 may be rectangular. The first dimension of the boundary 340 along the X-direction is denoted as a cell width W, and the second dimension of the boundary 340 along the Y-direction is denoted as a cell height H. Where the two-port SRAM cell 300 is repeated in a memory array, the cell width W may represent and be referred to as a memory cell pitch in the memory array along the X-direction, and the cell height H may represent and be referred to as a memory cell pitch in the memory array along the Y-direction.

The cell size of the two-port SRAM cell 300 is W×H, in which the cell width W is about 4 times a poly pitch (e.g., a center-to-center distance between two adjacent gate structures along the X-direction) and the cell height H is about 2 times an isolation pitch (e.g., a center-to-center distance between two adjacent STI features along the Y-direction). Denoting an area of one poly pitch times one isolation pitch as a unit area, each unit area includes an intersection of a gate structure and an active region, and the two-port SRAM cell 300 utilizes a cell size of about 8 times a unit area in accommodating the seven transistors, namely the transistors PG-1, PG-2, PU-1, PU-2, PD-1, PD-2, and R-PG. The area utilization at the device layer of the SRAM cell 300 is considered efficient as there is only one unit area not utilized for forming a functional transistor but hosting an intersection of a CPODE feature and an active region instead.

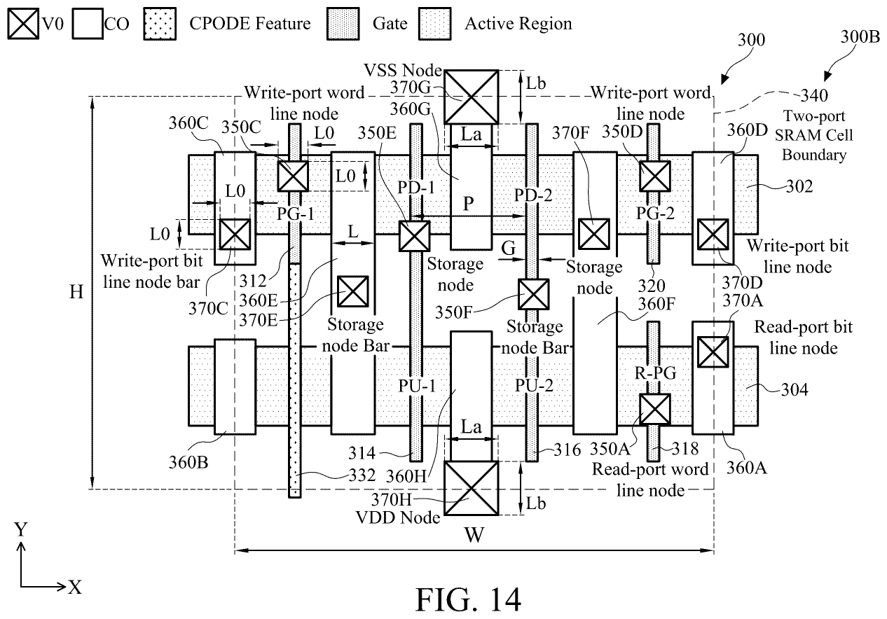

FIG. 14 illustrates a simplified diagrammatic layout 300B at the contact level (CO) and the via zero (V0) level of the two-port SRAM cell 300. Also, for reasons of aiding visual clarity, some features in the layout 300A devoted to the device layer (DL) are reproduced in FIG. 14, such as the active regions 302, 304, the gate structures 312-320, the CPODE feature 332, and the cell boundary 340, while numerous other features are omitted in FIG. 14.

A gate contact 350A electrically connects a gate of the read-port pass-gate transistor R-PG (formed by the gate structure 318) to the read-port word line node (R_WL). A gate contact 350C electrically connects a gate of the write-port pass-gate transistor PG-1 (formed by the gate structure 312) to the write-port word line node (W_WL). A gate contact 350D electrically connects a gate of the write-port pass-gate transistor PG-2 (formed by the gate structure 320) to the write-port word line node (W_WL). A gate contact 350E electrically connects a gate of the write-port pull-down transistor PD-1 (formed by the gate structure 314) and a gate of the write-port pull-up transistor PU-1 (also formed by the gate structure 314) to the storage node (SN). A gate contact 350F electrically connects a gate of the write-port pull-down transistor PD-2 (formed by the gate structure 316) and a gate of the write-port pull-up transistor PU-2 (also formed by the gate structure 316) to the complementary storage node (SNB).

A source/drain contact 360A and a source/drain contact via 370A landing thereon electrically connect a source region of the read-port pass-gate transistor R-PG to the read-port bit line node (R_BL). A source/drain contact 360B lands on a source/drain region adjacent to the CPODE feature 332 and stays electrically floating, as there is no corresponding source/drain contact via landing thereon. A source/drain contact 360C and a source/drain contact via 370C landing thereon electrically connect a source region of the write-port pass-gate transistor PG-1 to the write-port complementary bit line node (W_BLB). A source/drain contact 360D and a source/drain contact via 370D landing thereon electrically connect a source region of the write-port pass-gate transistor PG-2 to the write-port bit line node (W_BL). A source/drain contact 360E and a source/drain contact via 370E landing thereon electrically connect a common drain region of the write-port pass-gate transistor PG-1 and the write-port pull-down transistor PD-1 together with a drain region of the write-port pull-up transistor PU-1 to the complementary storage node (SNB). A source/drain contact 360F and a source/drain contact via 370F landing thereon electrically connect a common drain region of the write-port pass-gate transistor PG-2 and the write-port pull-down transistor PD-2 together with a common drain region of the write-port pull-up transistor PU-2 and the read-port pass-gate transistor R-PG to the storage node (SN). A source/drain contact 360G and a source/drain contact via 370G landing thereon electrically connect a common source region of the write-port pull-down transistor PD-1 and the write-port pull-down transistor PD-2 to the electrical ground node VSS. A source/drain contact 360H and a source/drain contact via 370H landing thereon electrically connect a common source region of the write-port pull-up transistor PU-1 and the write-port pull-up transistor PU-2 to the power voltage node VDD. In the illustrated embodiment, the source/drain contacts 360A-360H each are elongated and have a longitudinal direction in the Y-direction, which is parallel to the extending directions of gate structures.

Still referring to FIG. 14, the gate contacts 350A/C-F and the source/drain contact vias 370A/C-F may have the same size in a top view. For example, each of the gate contacts 350A/C-F and the source/drain contact vias 370A/C-F may have a square shape with the same edge length L0 in the X-direction and in the Y-direction. Further in the illustrated embodiment, each of the source/drain contacts 360A-H may have the same width L measured in the X-direction, and the edge length L0 may be smaller than the width L. As a comparison, each of the source/drain contact vias 370G and 370H has a larger size, such as a first dimension La measured in the X-direction and a second dimension Lb measured in the Y-direction with La>L0 and Lb>L0. Further, the first dimension La may be larger than the width L. The source/drain contact vias 370G and 370H are electrically connected to the electrical ground node and power voltage node, respectively, whose resistances contribute more impacts to an SRAM cell's speed than other source/drain contact vias and gate contacts. The larger size of the source/drain contact vias 370G and 370H reduces respective source/drain contact via resistance and effectively improves circuit speed. In some embodiments, a range of La/L0 is from about 1 to about 3, and a range of Lb/L0 is from about 1 to about 3. In some embodiments, a range of La/G is from about 1 to about 3, and a range of Lb/G is from about 1 to about 3. In some embodiments, a range of La/L is from about 1 to about 3, and a range of Lb/L is from about 1 to about 3. The larger source/drain contact vias 370G and 370H may have an extra barrier (and/or glue) layer than the smaller gate contacts 350A/C-F and the source/drain contact vias 370A/C-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 370G and 370H are depicted as having the same size in the illustrated embodiment, they may have different sizes to meet various performance needs. For example, the source/drain contact via 370G may have the same size as the gate contacts 350A/C-F and the source/drain contact vias 370A/C-F (e.g., a square shape with the edge length L0), while the source/drain contact via 370H may have the larger size (La and Lb) to reduce IR drop from a power voltage line. Alternatively, the source/drain contact via 370H may have the same size as the gate contacts 350A/C-F and the source/drain contact vias 370A/C-F (e.g., a square shape with the edge length L0), while the source/drain contact via 370G may have the larger size (La and Lb) to reduce ground bounce from an electrical ground line.

Also shown in FIG. 14, the storage node SN includes the gate contact 350E and the source/drain contact via 370F positioned on two opposing sides of the gate structure 316. As to discuss in further detail below, a metal line at the M0 level extends in the X-direction to across the gate structure 316 and connects the gate contact 350E and the source/drain contact via 370F. In other words, an M0 metal line hangs over the gate structure 316 and provide the function of cross coupling between the gate contact 350E and the source/drain contact via 370F. Therefore, in the layout 300B, the gate contact 350E and the source/drain contact via 370F are positioned as being level in the Y-direction, such that a metal line extending in the X-direction may connect both. Similarly, the complementary storage node (storage node bar) SNB includes the gate contact 350F and the source/drain contact via 370E positioned on two opposing sides of the gate structure 314. As to discuss in further detail below, another metal line at the M0 level extends in the X-direction to across the gate structure 314 and connects the gate contact 350F and the source/drain contact via 370E. In other words, another M0 metal line hangs over the gate structure 314 and provide the function of cross coupling between the gate contact 350F and the source/drain contact via 370E. Therefore, in the layout 300B, the gate contact 350F and the source/drain contact via 370E are positioned as being level in the Y-direction, such that a metal line extending in the X-direction may connect both.

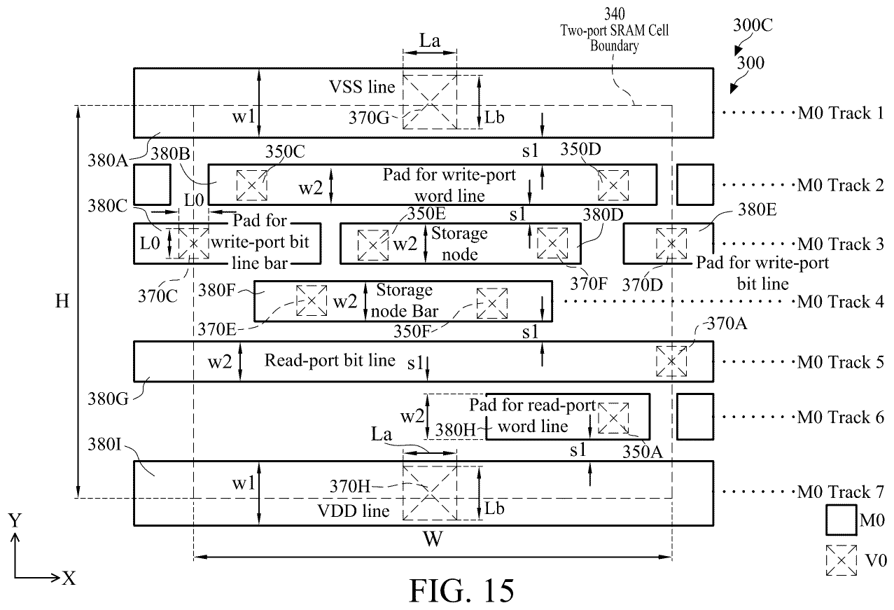

FIG. 15 illustrates a simplified diagrammatic layout 300C at the metal zero (M0) level of the two-port SRAM cell 300. Also, for reasons of aiding visual clarity, the gate contacts 350A/C-F and source/drain contact vias 370A/C-H at the via zero (V0) level are reproduced in FIG. 14, while numerous other features are omitted in FIG. 14.

At the M0 level, the SRAM cell 300 includes a plurality of metal tracks arranged in parallel. Particularly, in the illustrated embodiment of the layout 300C, the SRAM cell 100 includes seven metal tracks arranged in order from first (M0 Track 1) to seventh (M0 Track 7) along the Y-direction. The center lines of the metal tracks are represented by the dotted lines in FIG. 15. A distance between the center lines of the adjacent metal tracks is denoted as the metal track pitch.

One metal track may include a single metal line extending through the entire SRAM cell 300 along the X-direction. Such a metal line is denoted as a global metal line. Alternatively, one metal track may include one or more metal lines that do not extend through the entire SRAM cell 300. Such a metal line is denoted as a local metal line, or referred to as an island, a pad, or a landing pad. In the layout 300C, the first metal track “M0 Track 1” includes a global metal line 380A, which is a VSS line electrically coupled to the source/drain contact via 370G. The VSS line 380A is disposed on the upper boundary line of the SRAM cell 300 and shared with an adjacent SRAM cell. Disposed on the upper boundary line of the SRAM cell 300, the source/drain contact via 370G is also shared by the two adjacent SRAM cells. The second metal track “M0 Track 2” includes a local metal line 380B as a pad for the write-port word line (W_WL). The local metal line 380B is fully within the SRAM cell 300 and electrically connects to the gate contact 350C and the gate contact 350D. The third metal track “MO Track 3” includes three local metal lines 380C, 380D, and 380E. The local metal line 380C provides a pad for the write-port complimentary bit line (W_BLB). The local metal line 380C extends beyond a left edge of the SRAM cell 300 and may be shared with an adjacent SRAM cell. The local metal line 380D is fully within the SRAM cell 300, which belongs to the storage node (SN) and provides cross-coupling between the gate contact 350E and the source/drain contact via 370F. As discussed above, the local metal line 380D crosses over the gate structure 316. The local metal line 380E provides a pad for the write-port bit line (W_BL). The local metal line 380E extends beyond a right edge of the SRAM cell 300 and may be shared with an adjacent SRAM cell. The fourth metal track “M0 Track 4” includes a local metal line 380F, which belongs to the complementary storage node (SNB). The local metal line 380F is fully within the SRAM cell 300 and provides cross-coupling between the gate contact 350F and the source/drain contact via 370E. As discussed above, the local metal line 380F crosses over the gate structure 314. The fifth metal track “M0 Track 5” includes a global metal line 380G, which is a read-port bit line electrically coupled to the source/drain contact via 370A. The sixth metal track “M0 Track 6” includes a local metal line 380H. The local metal line 380H is fully within the SRAM cell 300 and provides a pad for the read-port word line (R_WL). The seventh metal track “M0 Track 7” includes a global metal line 3801, which is a VDD line electrically coupled to the source/drain contact via 370H. The VDD line 380I is disposed on the lower boundary line of the SRAM cell 300 and may be shared with an adjacent SRAM cell. Disposed on the lower boundary line of the SRAM cell 300, the source/drain contact via 370H is also shared by the two adjacent SRAM cells.

A width of the VSS line 380A is denoted as w1 with one half of w1 in one SRAM cell and another half of w1 in the adjacent SRAM cell. A width of the VDD line 380I may be substantially the same as the VSS line 380A with one half of w1 in one SRAM cell and another half of w1 in the adjacent SRAM cell. The other M0 metal lines 380B-380H may each have the same width denoted as w2. The spacing between two adjacent M0 metal lines may be uniform and denoted as s1. Thus, the SRAM cell height H equals w1+5*w2+6*s1. In the illustrated embodiment, the second dimension Lb of the larger source/drain contact vias 370G and 370H is smaller than the width w1 of the respective VSS line 380A and VDD line 380J (Lb<w1). Alternatively, the second dimension Lb of the larger source/drain contact vias 370G and 370H may equal the width w1 of the respective VSS line 380A and VDD line 380J (Lb=w1) to increase contact area and reduce contact resistance.

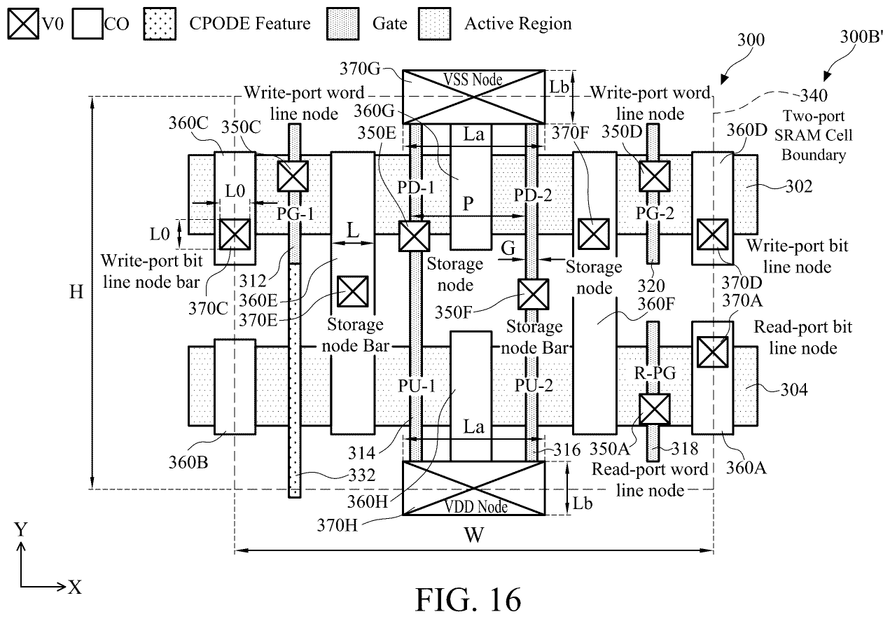

FIG. 16 illustrates an alternative diagrammatic layout 300B′ at the contact level (CO) and the via zero (V0) level of the two-port SRAM cell 300. Also, for reasons of aiding visual clarity, some features in the layout 300A devoted to the device layer (DL) are reproduced in FIG. 16, such as the active regions 302, 304, the gate structures 312-320, the CPODE feature 332, and the cell boundary 340, while numerous other features are omitted in FIG. 16. The gate contacts 350A/C-F and the source/drain contact vias 370A/C-F in the layout 300B′ may be substantially similar with the counterparts in the layout 300B. One difference is that the source/drain contact vias 370G and 370H in the layout 300B′ may be further enlarged to further reduce contact via resistance. For example, edges of the source/drain contact vias 370G and 370H may extend beyond outer edges of the gate structure 314 and the gate structure 316. State differently, the first dimension La may be larger than a sum of the poly pitch P and the gate width G (La>P+G). In furtherance of the embodiment, a portion of the gate structure 314 and a portion of the gate structure 316 may be directly under the source/drain contact vias 370G and 370H. In some embodiments, a range of La/L0 is from about 1 to about 5, and a range of Lb/L0 is from about 1 to about 5. In some embodiments, a range of La/G is from about 1 to about 5, and a range of Lb/G is from about 1 to about 5. In some embodiments, a range of La/L is from about 1 to about 5, and a range of Lb/L is from about 1 to about 5. In some embodiments, Lb may be smaller than or equal to the width w1 (Lb≤w1) of the VSS line and VDD line in the M0 level (FIG. 15).

Similar to the discussion above, the larger source/drain contact vias 370G and 370H may have an extra barrier (and/or glue) layer than the smaller gate contacts 350A/C-F and the source/drain contact vias 370A/C-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 370G and 370H are depicted as having the same size in the illustrated embodiment, they may have different sizes to meet various performance needs. For example, the source/drain contact via 370G may have the same size as the gate contacts 350A/C-F and the source/drain contact vias 370A/C-F (e.g., a square shape with the edge length L0), while the source/drain contact via 370H may have the larger size (La and Lb) to reduce IR drop from a power voltage line. Alternatively, the source/drain contact via 370H may have the same size as the gate contacts 350A/C-F and the source/drain contact vias 370A/C-F (e.g., a square shape with the edge length L0), while the source/drain contact via 370G may have the larger size (La and Lb) to reduce ground bounce from an electrical ground line.

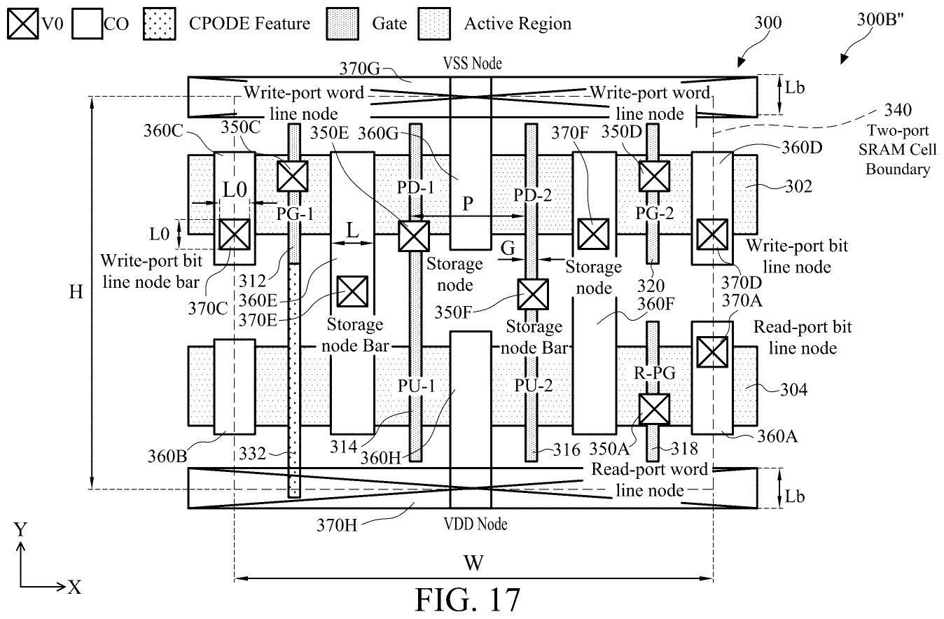

FIG. 17 illustrates an alternative diagrammatic layout 100B″ at the contact level (CO) and the via zero (V0) level of the two-port SRAM cell 300. Also, for reasons of aiding visual clarity, some features in the layout 300A devoted to the device layer (DL) are reproduced in FIG. 17, such as the active regions 302, 304, the gate structures 312-320, the CPODE feature 332, and the cell boundary 340, while numerous other features are omitted in FIG. 17. The gate contacts 350A/C-F and the source/drain contact vias 370A/C-F in the layout 300B″ may be substantially similar with the counterparts in the layout 300B′. One difference is that the source/drain contact vias 370G and 370H in the layout 300B′ may be further enlarged to further reduce contact via resistance. For example, the source/drain contact vias 370G and 370H may have a form of a rail that extends through the cell boundary 340 in the X-direction. The second dimension Lb of the source/drain contact vias 370G and 370H may be larger, or alternatively smaller, than the edge length L0 of other source/drain contact vias and gate contacts. In some embodiments, a range of Lb/L0 is from about 0.3 to about 5. In some embodiments, a range of Lb/G is from about 0.3 to about 5. In some embodiments, a range of Lb/L is from about 0.3 to about 5. In some embodiments, Lb may be smaller than or equal to the width w1 (Lb≤w1) of the VSS line and VDD line in the M0 level (FIG. 15).

Similar to the discussion above, the larger source/drain contact vias 370G and 370H may have an extra barrier (and/or glue) layer than the smaller gate contacts 350A/C-F and the source/drain contact vias 370A/C-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 370G and 370H are depicted as having the same size in the illustrated embodiment, they may have different sizes to meet various performance needs. For example, the source/drain contact via 370G may have the same size as the gate contacts 350A/C-F and the source/drain contact vias 370A/C-F (e.g., a square shape with the edge length L0), while the source/drain contact via 370H may have the larger size to reduce IR drop from a power voltage line. Alternatively, the source/drain contact via 370H may have the same size as the gate contacts 350A/C-F and the source/drain contact vias 370A/C-F (e.g., a square shape with the edge length L0), while the source/drain contact via 370G may have the larger size to reduce ground bounce from an electrical ground line.

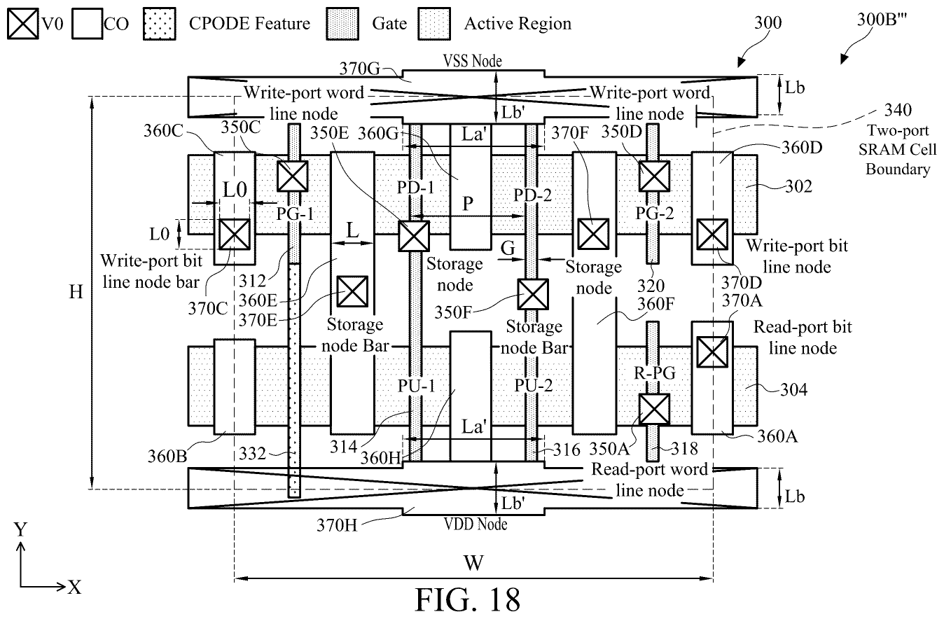

FIG. 18 illustrates an alternative diagrammatic layout 300B′″ at the contact level (CO) and the via zero (V0) level of the two-port SRAM cell 300. Also, for reasons of aiding visual clarity, some features in the layout 300A devoted to the device layer (DL) are reproduced in FIG. 18, such as the active regions 302, 304, the gate structures 312-320, the CPODE feature 332, and the cell boundary 340, while numerous other features are omitted in FIG. 18. The gate contacts 350A/C-F and the source/drain contact vias 370A/C-F in the layout 300B′″ may be substantially similar with the counterparts in the layout 300B″. One difference is that the source/drain contact vias 370G and 170H in the layout 300B″ may be further enlarged to further reduce contact via resistance. For example, the source/drain contact vias 370G and 370H may have a form of a rail that extends through the cell boundary 340 in the X-direction and a jog portion overlaying the respective source/drain contacts 360G and 360H. The jog portion has a first dimension La′ and a larger second dimension Lb′ (Lb′>Lb). In some embodiments, a range of Lb′/Lb is from about 1 to about 3. Edges of the jog portion of the source/drain contact vias 370G and 370H may extend beyond outer edges of the gate structure 314 and the gate structure 316. State differently, the first dimension La′ of the jog portion may be larger than a sum of the poly pitch P and the gate width G (La>P+G). In furtherance of the embodiment, a portion of the gate structure 314 and a portion of the gate structure 316 may be directly under the jog portion of the source/drain contact vias 370G and 370H. In some embodiments, a range of Lb/L0 is from about 0.3 to about 5. In some embodiments, a range of Lb/G is from about 0.3 to about 5. In some embodiments, a range of Lb/L is from about 0.3 to about 5. In some embodiments, Lb′ may be smaller than or equal to the width w1 (Lb<Lb′≤w1) of the VSS line and VDD line in the M0 level (FIG. 15).

Similar to the discussion above, the larger source/drain contact vias 370G and 370H may have an extra barrier (and/or glue) layer than the smaller gate contacts 350A/C-F and the source/drain contact vias 370A/C-F, such as an additional liner of a compound of Ti/TiN surrounding the bulk metal, to block the diffusion of tungsten atoms form the bulk metal. In other words, the larger contact vias and the smaller contact vias (and smaller gate contacts) may have different material compositions. Notably, although the source/drain contact vias 370G and 370H are depicted as having the same size in the illustrated embodiment, they may have different sizes to meet various performance needs. For example, the source/drain contact via 370G may have the same size as the gate contacts 350A/C-F and the source/drain contact vias 370A/C-F (e.g., a square shape with the edge length L0), while the source/drain contact via 370H may have the larger size to reduce IR drop from a power voltage line. Alternatively, the source/drain contact via 370H may have the same size as the gate contacts 350A/C-F and the source/drain contact vias 370A/C-F (e.g., a square shape with the edge length L0), while the source/drain contact via 370G may have the larger size to reduce ground bounce from an electrical ground line.

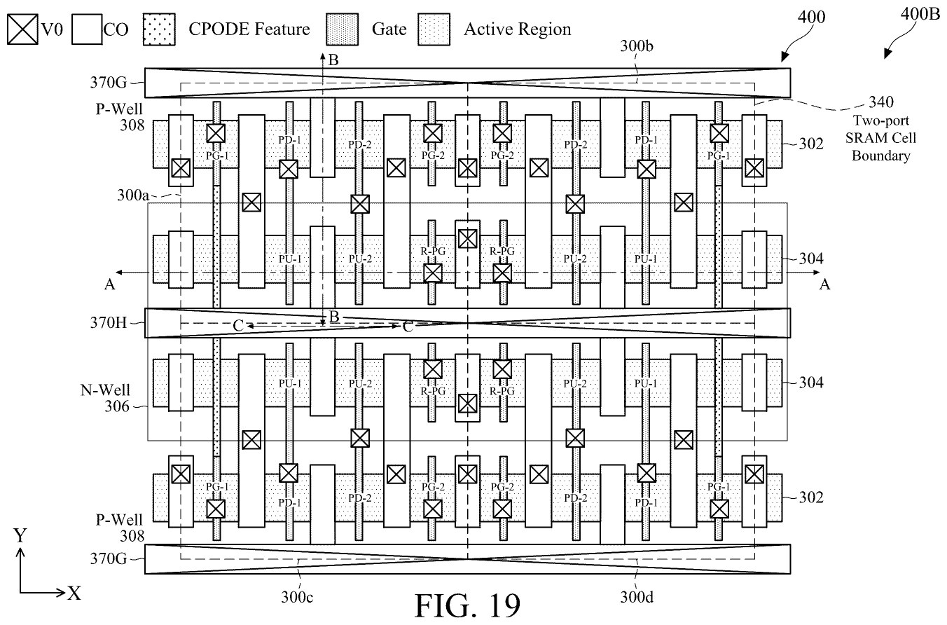

FIG. 19 illustrates a diagrammatic layout 400B of an SRAM array 400 according to the present disclosure. Referring to FIG. 19, a plurality of two-port SRAM cells 300a, 300b, 300c, and 300d are arranged in the X-direction and the Y-direction, forming a 2×2 array of SRAM cells. Each SRAM cell in the array may use the layout of the SRAM cell 300 as depicted in FIG. 13. In some embodiments, two adjacent SRAM cells in the X-direction are line symmetric with respect to a common boundary therebetween, and two adjacent SRAM cells in the Y-direction are line symmetric with respect to a common boundary therebetween. That is, the SRAM cell 300b is a duplicate cell for the SRAM cell 300a but flipped over the Y-axis; the SRAM cell 300c is a duplicate cell for the SRAM cell 300a but flipped over the X-axis; and the SRAM cell 300d is a duplicate cell for the SRAM cell 300b but flipped over the X-axis. FIG. 10 has been simplified for the sake of clarity to better understand the inventive concepts of the present disclosure. For example, active regions, gate structures, gate contacts, CPODE features, source/drain contacts, source/drain contact vias, N-well, P-well, and cell boundaries for shown, while some other features are omitted in FIG. 19.

The SRAM array 400 includes well regions 306 and 308 alternately arranged along the Y-axis. In other words, every P-well region 308 is next to an N-well region 306 which is next to another P-well region 308, and this pattern repeats. In the illustrated embodiment as in FIG. 19, the gate structures in each two-port SRAM cell do not extend beyond the respective cell boundary, and each CPODE feature is shared by two neighboring SRAM cells arranged in the Y-direction. The distance along the X-direction between adjacent CPODE features (also denoted as CPODE-to-CPODE pitch) is 7 times a poly pitch.

In the depicted embodiment, the source/drain contact vias 370G and 370H are in the form of a rail as depicted in FIG. 19. Alternatively, the source/drain contact vias 370G and 370H may be in the form of a patch as depicted in FIGS. 14 and 16, or in the form of a rail with a jog portion as depicted in FIG. 18. Each of the source/drain contact vias 370G and 370H is shared by adjacent SRAM cells. For example, the source/drain contact via 370H, which is electrically coupled to the power voltage VDD, is positioned between two P-type active regions (over the N-well 306) and shared by the SRAM cells 300a, 300b, 300c, and 300d. Similarly, the source/drain contact via 370G, which is electrically coupled to the electrical ground VSS, is positioned between two N-type active regions (over the P-well 308) and shared by the adjacent four SRAM cells.

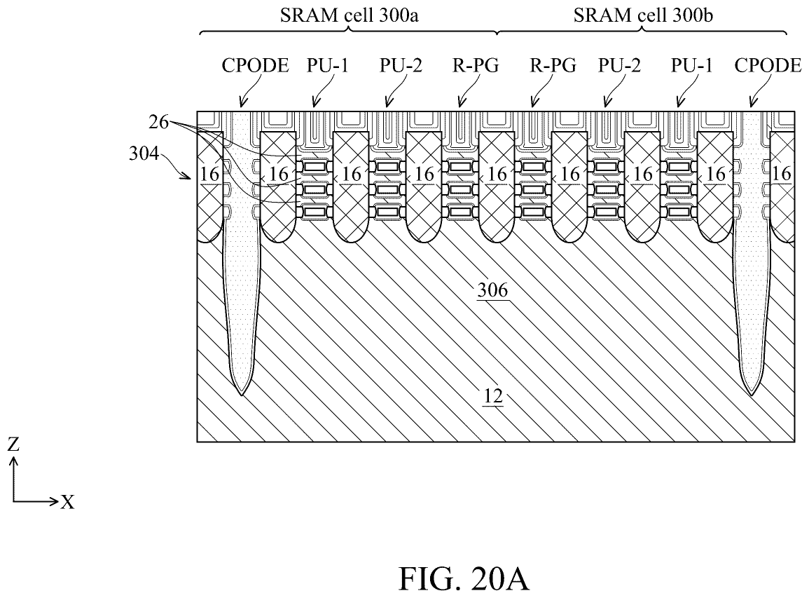

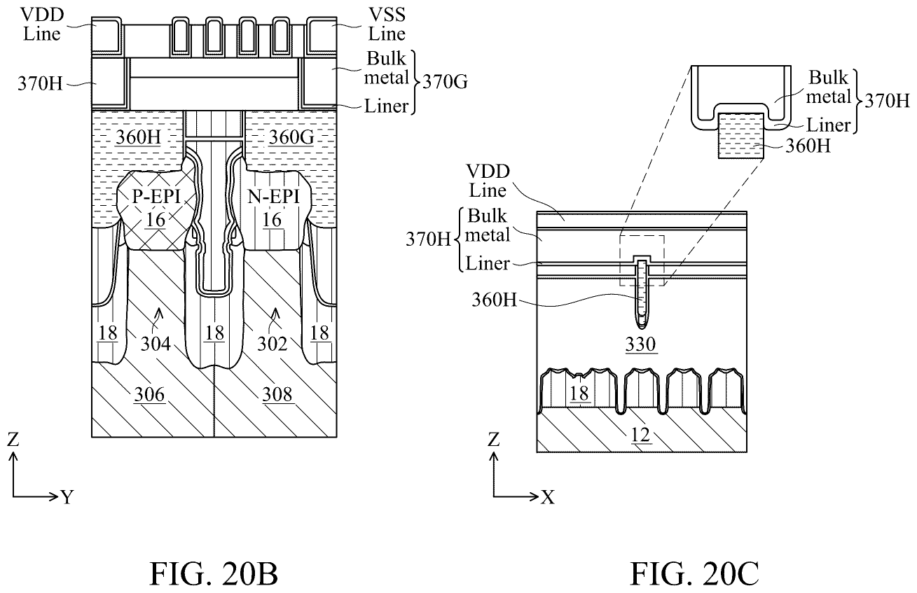

FIG. 20A is a fragmentary diagrammatic cross-sectional view along A-A line of FIG. 19, which cuts the active region 304 along its lengthwise direction, according to various aspects of the present disclosure. FIG. 20B is a fragmentary diagrammatic cross-sectional view along B-B line of FIG. 19, which cuts source/drain regions along a middle line of the SRAM cell 300a, according to various aspects of the present disclosure. FIG. 20C is a fragmentary diagrammatic cross-sectional view along C-C line of FIG. 19, which cuts the source/drain contact via 370H along a boundary line between the SRAM cells 300a and 300c, according to various aspects of the present disclosure.

Referring to FIGS. 20A-C collectively, the active region 304 extends continuously through the SRAM cells 300a, 300b (and other SRAM cells in the same row of the array 400) but sandwiched by two CPODE features. The CPODE features replace the otherwise metal gate structures closest to the cell edges. The distance between the CPODE features (CPODE-to-CPODE pitch) is 7 times a poly pitch. Between the CPODE features, the active region 304 includes channel regions that is comprised of the nanostructures 26 and source/drain features 16 abut the ends of the nanostructures 26. The gate structures wrap around the nanostructures 26 and form the transistors PU-1, PU-2, R-PG in the SRAM cell 300a and the transistors R-PG, PU-2, PU-1 in the SRAM cell 300b. The active region 304 is disposed over the N-well 306, and the active region 302 is disposed over the P-well 308. The source/drain features 16 formed on the active region 304 is p-type epitaxial features, and the source/drain features 16 formed on the active region 302 is n-type epitaxial features. The source/drain contact 360H electrically connects to the source/drain features 16 formed on the active region 304, and the source/drain contact 360G electrically connects to the source/drain features 16 formed on the active region 302. The source/drain contact via 370H is sandwiched between the source/drain contact 360H and the VDD line in the M0 level, and the source/drain contact via 370G is sandwiched between the source/drain contact 360G and the VSS line in the M0 level. Due to the larger size of the source/drain contact vias 370H and 370G, a liner (such as a compound of Ti/TiN) may function as a barrier layer and/or a glue layer in surrounding a bulk metal (e.g., tungsten). As a comparison, gate contacts and other source/drain contact vias may include the bulk metal but free of the liner. FIG. 20C illustrates the source/drain contact via 370H in the form of a rail extending parallel with the VDD line or alternatively as a patch in the region circled by the broken line. In either form, a bottom surface of the source/drain contact via 370H is larger than the source/drain contact 360H, such that an etching process during the formation of the source/drain contact via 370H may extend the bottom surface of the source/drain contact via 370H below a top surface of the source/drain contact 360H, such as for a vertical distance of 1 nm to about 4 nm. In other words, the top portion of the source/drain contact 360H may be partially embedded in the bottom portion of the source/drain contact via 370H for a vertical distance of 1 nm to about 4 nm.

The multi-port SRAM cells and the corresponding layouts illustrated in various exemplary embodiments of the present disclosure provide better cell area utilization and reduced contact via resistance, which in turn shrinks a cell size needed to implement a multi-port SRAM cell without sacrificing overall contact resistance in the power routing. In some embodiments, the layout designs of the metal interconnect structures indicate a two-port (2P) SRAM cell with enlarged source/drain contact vias for VDD lines and/or VSS lines. Further, embodiments of the present disclosure can be readily integrated into existing semiconductor manufacturing processes.

In one exemplary aspect, the present disclosure is directed to a memory cell. The memory cell includes first and second active regions and first and second gate structures. Each of the first and second active regions extends lengthwise in a first direction. Each of the first and second gate structures extends lengthwise in a second direction that is perpendicular to the first direction. The first gate structure engages the first and second active regions in forming a first pull-down transistor and a first pull-up transistor, respectively. The second gate structure engages the first and second active regions in forming a second pull-down transistor and a second pull-up transistor, respectively. The memory cell also includes a first source/drain contact via electrically coupled to a first common source/drain of the first and second pull-down transistors, a second source/drain contact via electrically coupled to a second common source/drain of the first and second pull-up transistors, a first gate contact electrically coupled to the first gate structure, and a second gate contact electrically coupled to the second gate structure. One of the first and second source/drain contact vias has an area larger than either of the first and second gate contacts in a top view of the memory cell. In some embodiments, the first source/drain contact via electrically couples to an electrical ground of the memory cell, and the second source/drain contact via electrically couples to a power supply of the memory cell. In some embodiments, the first and second source/drain contact vias have a same area, and the first and second gate contacts have a same area. In some embodiments, the first and second source/drain contact vias include a material composition different from the first and second gate contacts. In some embodiments, the first and second source/drain contact vias have different areas. In some embodiments, the first source/drain contact via includes a material composition different from the second source/drain contact via. In some embodiments, the first and second gate structures have a gate pitch and a gate width, and a length of the one of the first and second source/drain contact vias measured in the first direction is larger than a sum of the gate pitch and the gate width. In some embodiments, a portion of the first and second gate structures is directly under the one of the first and second source/drain contact vias. In some embodiments, the one of the first and second source/drain contact vias extends beyond opposing edges of the memory cell along the first direction. In some embodiments, the one of the first and second source/drain contact vias includes a jog portion with a width larger than other portions of the one of the first and second source/drain contact vias. In some embodiments, the first gate contact electrically couples to a storage node of the memory cell, and the second gate contact electrically couples to a complimentary storage node of the memory cell.

In another exemplary aspect, the present disclosure is directed to a semiconductor device. The semiconductor device includes first and second active regions each extending lengthwise in a first direction, first and second gate structures each extending lengthwise in a second direction different from the first direction, a first contact disposed on the first active region and between the first and second gate structures, a first contact via disposed on the first contact and electrically connected to the first contact, a second contact disposed on the second active region and between the first and second gate structures, a second contact via disposed on the second contact and electrically connected to the second contact, a third contact disposed on both of the first and second active regions, a fourth contact disposed on both of the first and second active regions, the first and second gate structures being between the third and fourth contacts along the first direction, a third contact via disposed on the third contact and electrically connected to the third contact, and a fourth contact via disposed on the fourth contact and electrically connected to the fourth contact, one of the first and second contact vias being larger than one of the third and fourth contact vias in a top view of the semiconductor device. In some embodiments, the first contact via is electrically connected to an electrical ground of the semiconductor device, and the second contact via is electrically connected to a power supply of the semiconductor device. In some embodiments, a length of the one of the first and second contact vias measured in the first direction is larger than a width of a corresponding one of the first and second contacts measured in the first direction. In some embodiments, the length of the one of the first and second contact vias measured in the first direction is larger than a distance between two outward facing sidewalls of the first and second gate structures measured in the first direction. In some embodiments, a portion of the first and second gate structures is directly under the one of the first and second contact vias. In some embodiments, the semiconductor device also includes a metal line extending in the first direction and electrically connected to the one of the first and second contact vias, the metal line and the one of the first and second contact vias substantially having a same width measured in the second direction.

In yet another exemplary aspect, the present disclosure is directed to a semiconductor device. The semiconductor device includes a device layer including a plurality of first transistors in a write-port of a static random-access memory (SRAM) cell and at least a second transistor in a read-port of the SRAM cell, a metal line layer disposed on the device layer and electrically coupled to the first and second transistors in the device layer, the metal line layer including a power supply line, an electrical ground line, and a plurality of signal lines, a first contact via disposed between the device layer and the metal line layer, the first contact via being electrically coupled to the power supply line, a second contact via disposed between the device layer and the metal line layer, the second contact via being electrically coupled to the electrical ground line, and a plurality of third contact vias disposed between the device layer and the metal line layer, the third contact vias being electrically coupled to the signal lines, each of the first and second contact vias having an area larger than any of the third contact vias in a top view of the semiconductor device. In some embodiments, the first and second contact vias are electrically coupled to the first transistors and not the second transistor. In some embodiments, the semiconductor device includes a first contact directly under the first contact via, and a second contact directly under the second contact via, each of the first and second contacts having a width smaller than a width of a respective one of the first and second contact vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit cell, comprising:
first and second active regions;
first and second gate structures, wherein the first gate structure engages the first and second active regions in forming a first transistor and a second transistor, respectively, and the second gate structure engages the first and second active regions in forming a third transistor and a fourth transistor, respectively, wherein the first and third transistors are of a first conductivity type, and the second and fourth transistors are of a second conductivity type that is opposite to the first conductivity type;
a first source/drain contact electrically coupled to a first common source/drain of the first and third transistors;
a first source/drain contact via electrically coupled to the first source/drain contact;
a second source/drain contact electrically coupled to a second common source/drain of the second and fourth transistors;
a second source/drain contact via electrically coupled to the second source/drain contact;
a first gate contact electrically coupled to the first gate structure; and
a second gate contact electrically coupled to the second gate structure,
wherein the first source/drain contact via has an area larger than either one of the first and second gate contacts when viewed from top.

2. The circuit cell of claim 1, wherein the circuit cell is a memory cell.

3. The circuit cell of claim 2, wherein the memory cell is a static random-access memory (SRAM) cell.

4. The circuit cell of claim 1, wherein the second source/drain contact via has an area larger than either one of the first and second gate contacts when viewed from top.

5. The circuit cell of claim 1, further comprising:
a multilayer interconnect structure over the first and second active regions and the first and second gate structures, wherein the multilayer interconnect structure includes a plurality of interconnect layers, a bottommost one of the interconnect layers includes a first metal line electrically coupled to the first source/drain contact via and a second metal line electrically coupled to the second source/drain contact via.

6. The circuit cell of claim 5, wherein the first metal line is an electrical ground line, and the second metal line is a power supply line.

7. The circuit cell of claim 5, wherein the first source/drain contact via has an elongated shape, and a longitudinal direction of the first source/drain contact via aligns with a longitudinal direction of the first metal line.

8. The circuit cell of claim 1, wherein the first source/drain contact via has an elongated shape, and along a longitudinal direction of the first source/drain contact via, the first source/drain contact via fully extends through a boundary of the circuit cell.

9. The circuit cell of claim 1, wherein the first source/drain contact via has an elongated shape, and measured along a direction perpendicular to a longitudinal direction of the first source/drain contact via, the first source/drain contact via has a non-uniform width.

10. The circuit cell of claim 1, wherein the first source/drain contact via has an elongated shape, the first source/drain contact via has first and second edges opposing to each other and spaced apart along a longitudinal direction of the first source/drain contact via, and along the longitudinal direction of the first source/drain contact via the first and second gate structures are positioned between the first and second edges of the first source/drain contact via.

11. A circuit cell, comprising:
first and second active regions each extending lengthwise in a first direction;
first and second gate structures each extending lengthwise in a second direction different from the first direction;
a first contact disposed on the first active region and between the first and second gate structures;
a first contact via disposed on the first contact and electrically connected to the first contact;
a second contact disposed on the second active region and between the first and second gate structures;
a second contact via disposed on the second contact and electrically connected to the second contact;
a third contact disposed on both of the first and second active regions;
a fourth contact disposed on both of the first and second active regions, wherein the first and second gate structures are between the third and fourth contacts along the first direction;
a third contact via disposed on the third contact and electrically connected to the third contact; and
a fourth contact via disposed on the fourth contact and electrically connected to the fourth contact,
wherein, when viewed from top, each of the first and second contact vias has a length measured along the first direction that is larger than each of the third and fourth contact vias.

12. The circuit cell of claim 11, wherein the first contact via is electrically connected to an electrical ground of the circuit cell, and the second contact via is electrically connected to a power supply of the circuit cell.

13. The circuit cell of claim 11, wherein the first contact via has first and second edges opposing to each other and spaced apart along the first direction, the first contact has first and second edges opposing to each other and spaced apart along the first direction, and along the first direction the first and second edges of the first contact are positioned between the first and second edges of the first contact via.

14. The circuit cell of claim 11, wherein the first contact via has first and second edges opposing to each other and spaced apart along the first direction, and along the first direction two outward facing sidewalls of the first and second gate structures are positioned between the first and second edges of the first contact via.

15. The circuit cell of claim 11, further comprising:
a metal line extending in the first direction and electrically connected to the first contact via, wherein a longitudinal direction of the first contact via aligns with a longitudinal direction of the metal line.

16. The circuit cell of claim 15, wherein the metal line and the first contact via substantially have a same width measured in the second direction.

17. A semiconductor device, comprising:
a first cell comprising a first active region extending lengthwise in a first direction, first and second gate structures extending lengthwise in a second direction different from the first direction and across the first active region;
a second cell comprising a second active region extending lengthwise in the second direction, third and fourth gate structures extending lengthwise in the second direction and across the second active region, the first and second cells sharing a common boundary line extending along the first direction;
a contact extending lengthwise along the second direction and electrically coupled to the first and second active regions, the contact positioned between the first and second gate structures and between the third and fourth gate structures; and
a contact via disposed on the contact and in electrical coupling with the contact, the contact via having an elongated shape and extending lengthwise along the first direction.

18. The semiconductor device of claim 17, wherein when viewed from top the contact via overlaps with the common boundary line.

19. The semiconductor device of claim 17, wherein when viewed from top the contact extends through the common boundary line.

20. The semiconductor device of claim 17, further comprising:
a first gate contact disposed on the first gate structure and in electrical coupling with the first gate structure;
a second gate contact disposed on the second gate structure and in electrical coupling with the second gate structure;
a third gate contact disposed on the third gate structure and in electrical coupling with the third gate structure; and
a fourth gate contact disposed on the fourth gate structure and in electrical coupling with the fourth gate structure,
wherein when viewed from top the contact via has an area larger than any one of the first, second, third, and fourth gate contacts.
